(19) United States
(12) Patent Application Publication
(10) Pub. No.: US 2014/0368288 A1
(43) Pub. Date: Dec. 18, 2014

(54) RESONATOR ELEMENT, RESONATOR, OSCILLATOR, ELECTRONIC DEVICE, AND MOVING OBJECT

(71) Applicant: SEIKO EPSON CORPORATION, Tokyo (JP)

(72) Inventor: Akinori YAMADA, Ina-shi (JP)

(21) Appl. No.: 14/308,161

(22) Filed: Jun. 18, 2014

(30) Foreign Application Priority Data
Jun. 18, 2013 (JP) 2013-128014

(51) Int. Cl. H03H 9/21; H03B 5/32

(52) U.S. Cl. CPC H03H 9/21; H03B 5/32
USPC 331/156; 310/348

(57) ABSTRACT

A resonator element includes a base portion, a pair of vibrating arms that extend in a first direction from the base portion and are arranged along a second direction perpendicular to the first direction, and a supporting arm that extends in the first direction from the base portion and is disposed between the pair of vibrating arms when seen in a plan view.

### CROSS REFERENCE

The entire disclosure of Japanese Patent Application No. 2013-128014 filed Jun. 18, 2013 is expressly incorporated by reference herein.

### BACKGROUND

1. Technical Field

The invention relates to a resonator element, a resonator, an oscillator, an electronic device, and a moving object.

2. Related Art

Hitherto, resonator elements using quartz crystal have been known. Such resonator elements have excellent frequency-temperature characteristics. Accordingly, the resonator elements are widely used as reference frequency sources, signal transmission sources, and the like of various electronic devices.

A resonator element disclosed in JP-A-2011-19159 includes a base portion and a pair of vibrating arms collaterally extending from the base portion. The resonator element is fixed to a package through conductive adhesive members by two fixation portions provided in the base portion. However, in such a configuration, the two fixation portions are disposed at a position where vibrations of the vibrating arms are likely to be transmitted. Accordingly, when a vibrating piece is reduced in size, there is a concern that the resonator element may be greatly affected by vibration leakage.

In addition, a resonator element disclosed in JP-A-2002-141770 includes a base portion, a pair of vibrating arms collaterally extending from the base portion, and a supporting arm extending between the pair of vibrating arms from the base portion. The resonator element is fixed to a package through conductive adhesive members by two fixation portions provided in the supporting arm.

However, in such a configuration, there is a problem in that a Q value may be decreased according to the positions of the two fixation portions in the supporting arm and a positional relationship between the two fixation portions.

### SUMMARY

An advantage of some aspects of the invention is to provide a resonator element capable of reducing a decrease in the Q value, and a resonator, an oscillator, an electronic device, and a moving object which include the resonator element.

The invention can be implemented as the following application examples.

### Application Example 1

This application example is directed to a resonator element including a base portion; a pair of vibrating arms that extend in a first direction from the base portion and are lined up along a second direction perpendicular to the first direction; and a supporting arm that extends in the first direction from the base portion and is disposed between the pair of vibrating arms when seen in a plan view. The supporting arm is provided with a fixed region that is attached to an object through a fixation member between a centroid of the resonator element and the base portion when seen in a plan view.

According to this configuration, the resonator element capable of reducing a reduction in a Q value is obtained.

### Application Example 2

This application example is directed to the resonator element according to the application Example described above, wherein the fixed region has a length along the first direction which is larger than a length along the second direction.

According to this configuration, the resonator element capable of further reducing a reduction in a Q value is obtained.

### Application Example 3

This application example is directed to the resonator element according to the application example described above, wherein the fixed region has a length along the first direction which is equal to or greater than twice and equal to or less than five times the length along the second direction.

Since the fixed region is larger in length in the longitudinal direction of the resonator element, it is possible to fix the resonator element to a case in a balanced manner.

### Application Example 4

This application example is directed to the resonator element according to the application example described above, wherein, when a distance along the first direction between the centroid and the base portion when seen in a plan view is set to L10, the distance along the first direction between a center of the fixed region in the first direction and the base portion is equal to or greater than 0.15×L10 and equal to or less than 0.30×L10.

Since this range is a region which is not likely to be affected by vibration of the vibrating arms, the fixed region is disposed centering on this position. Thus, the resonator element in which a reduction in a Q value due to vibration leakage is further reduced is obtained.

### Application Example 5

This application example is directed to the resonator element according to the application example described above, wherein, when a distance along the first direction between the centroid and the base portion when seen in a plan view is set to L10, the distance of the fixed region along the first direction is equal to or greater than 0.589×L10 and equal to or less than L10.

The resonator element in which a reduction in a Q value due to vibration leakage is further reduced is obtained.

### Application Example 6

This application example is directed to the resonator element according to the application example described above, wherein the supporting arm overlaps the centroid when seen in a plan view.

Thus, the resonator element capable of reducing the influence of vibration of the vibrating arms and reducing a reduction in a Q value caused by vibration leakage is obtained.

### Application Example 7

This application example is directed to the resonator element according to the application example described above, wherein the fixed region includes, when seen in a plan view, a first fixation portion, and a second fixation portion which is spaced apart from the first fixation portion and is positioned on the distal end side of the supporting arm with respect to the first fixation portion.

Thus, it is possible to reduce contact between the fixation members in a state of being mounted onto an object.

### Application Example 8

This application example is directed to the resonator element according to the application example described above, wherein a distance along the first direction between the first fixation portion and the second fixation portion is equal to or greater than 20 μm.

Thus, it is possible to further reduce contact between the fixation members in a state of being mounted onto an object.

### Application Example 9

This application example is directed to a resonator including the resonator element according to the application example and a package that accommodates the resonator element.

Thus, a resonator with high reliability is obtained.

### Application Example 10

This application example is directed to an oscillator including the resonator element according to the application example and an oscillation circuit.

Thus, an oscillator with high reliability is obtained.

### Application Example 11

This application example is directed to an electronic device including the resonator element according to the application example.

Thus, an electronic device with high reliability is obtained.

### Application Example 12

This application example is directed to a moving object including the resonator element according to the application example.

Thus, a moving object with high reliability is obtained.

### BRIEF DESCRIPTION OF THE DRAWINGS

The invention will be described with reference to the accompanying drawings, wherein like numbers reference like elements.

FIG. 1 is a plan view of a resonator according to a first embodiment of the invention.

FIG. 2 is a cross-sectional view taken along line A-A of FIG. 1.

FIG. 3 is a top view of a resonator element included in the resonator shown in FIG. 1.

FIGS. 4A and 4B are plan views illustrating a function of the resonator element shown in FIG. 3.

FIG. 5 is a cross-sectional view taken along line B-B of FIG. 3.

FIG. 6 is a rear view of the resonator element shown in FIG. 3.

FIG. 7 is a top view showing another example of the resonator element shown in FIG. 3.

FIG. 8 is a cross-sectional view of a vibrating arm illustrating heat conduction during bending and vibration.

FIG. 9 is a graph showing a relationship between a Q value and f/fm.

FIG. 10A is a diagram showing an example of a resonator element used in a simulation, and FIG. 10B is a diagram showing a relationship between a holding position of the resonator element and a Q_{Leak} value.

FIG. 11 is a top view of a resonator element included in a resonator according to a second embodiment of the invention.

FIG. 12 is a top view of a resonator element included in a resonator according to a third embodiment of the invention.

FIG. 13 is a top view of a resonator element included in a resonator according to a fourth embodiment of the invention.

FIG. 14A is a diagram showing an example of a resonator element used in a simulation, and FIG. 14B is a diagram showing a relationship between a holding position of the resonator element and a Q_{Leak} value.

FIG. 15 is a top view of a resonator element included in a resonator according to a fifth embodiment of the invention.

FIG. 16 is a top view of a resonator element included in a resonator according to a sixth embodiment of the invention.

FIG. 17 is a top view of a resonator element included in a resonator according to a seventh embodiment of the invention.

FIG. 18 is a top view of a resonator element included in a resonator according to an eighth embodiment of the invention.

FIG. 19 is a cross-sectional view of the resonator shown in FIG. 18.

FIG. 20 is a cross-sectional view showing a preferred embodiment of an oscillator of the invention.

FIG. 21 is a perspective view showing a configuration of a mobile (or notebook) personal computer to which an electronic device including the resonator element according to the invention is applied.

FIG. 22 is a perspective view showing a configuration of a mobile phone (PHS is also included) to which an electronic device including the resonator element according to the invention is applied.

FIG. 23 is a perspective view showing a configuration of a digital still camera to which an electronic device including the resonator element according to the invention is applied.

FIG. 24 is a perspective view schematically showing a vehicle as an example of a moving object according to the invention.

### DESCRIPTION OF EXEMPLARY EMBODIMENTS

Hereinafter, a resonator element, a resonator, an oscillator, an electronic device, and a moving object according to the invention will be described in detail with reference to preferred embodiments shown in the diagrams.

### 1. Resonator

First, the resonator according to the invention will be described.

### First Embodiment

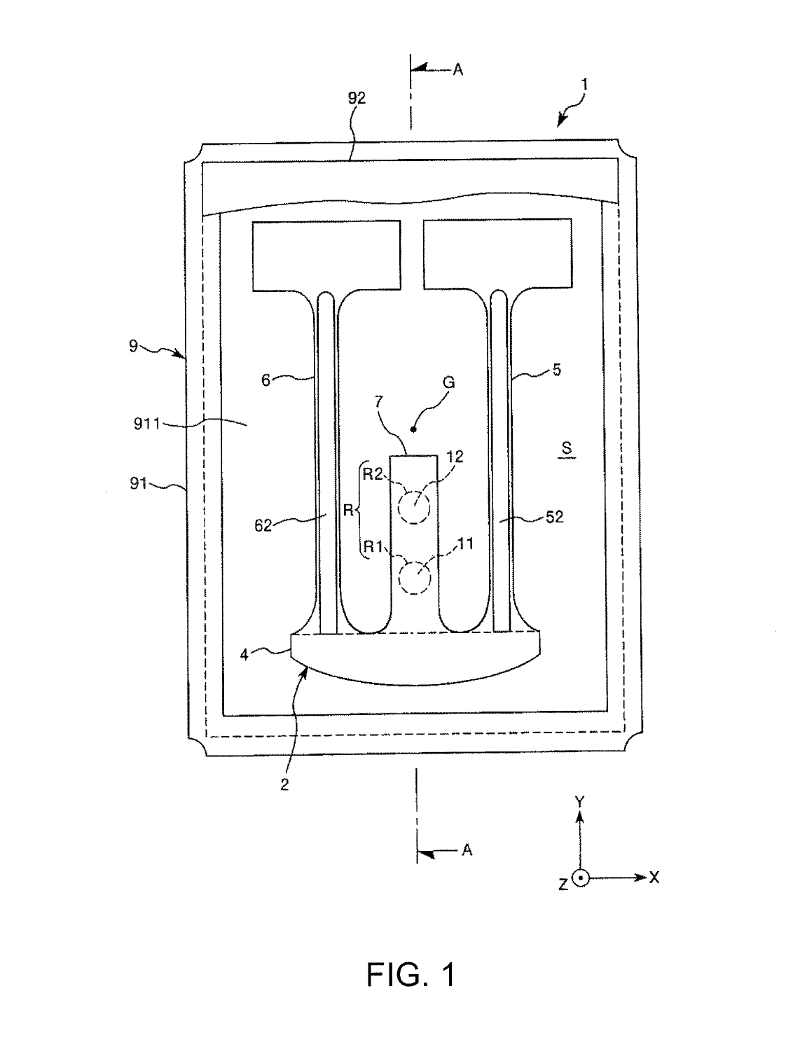

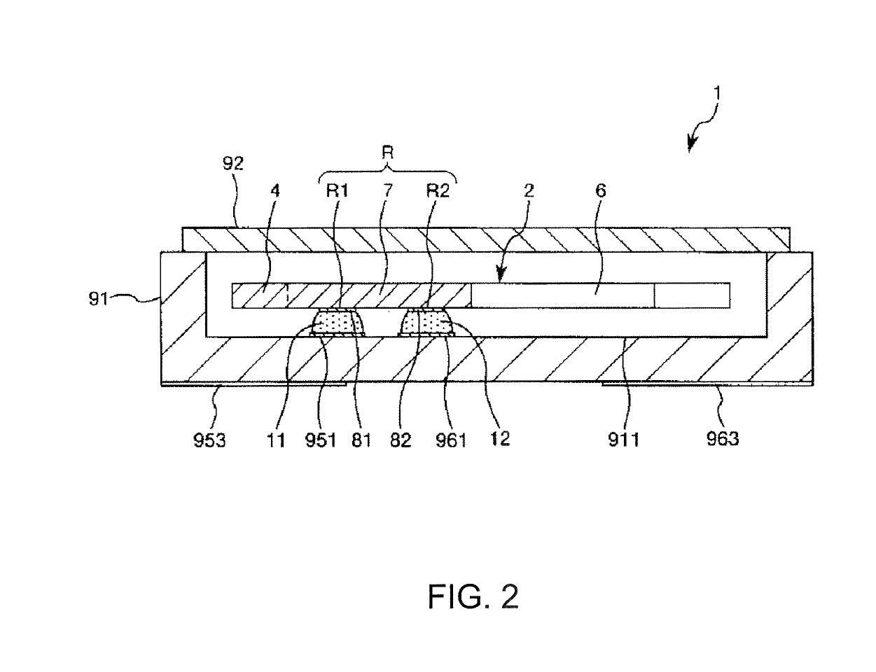

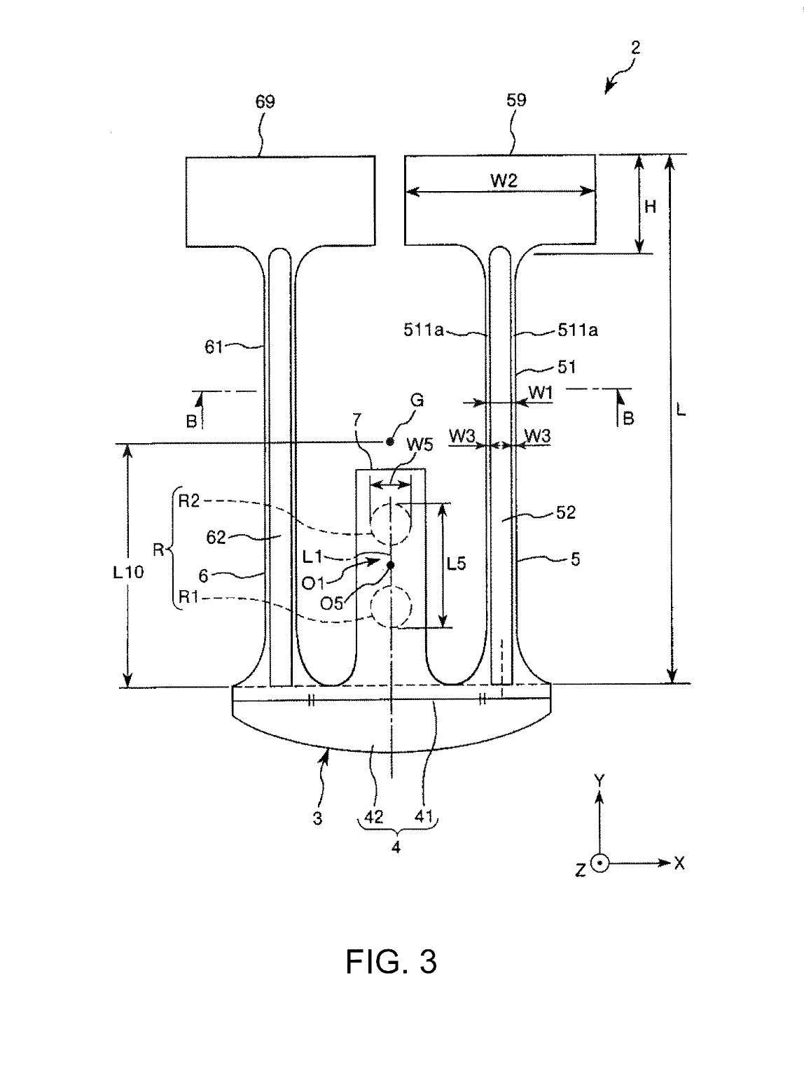

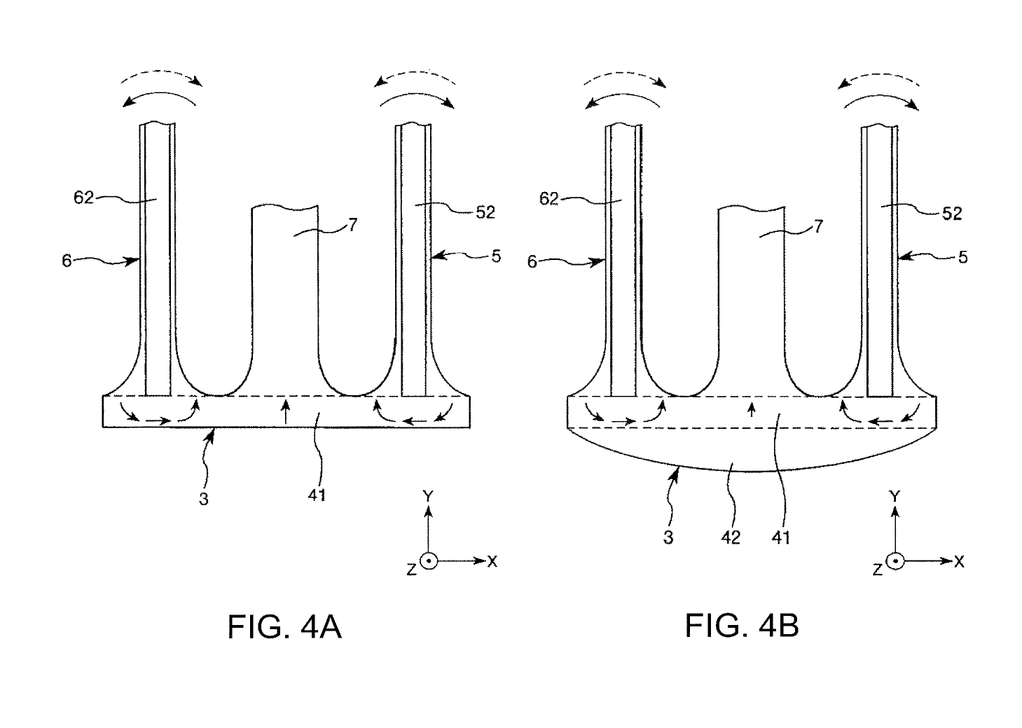

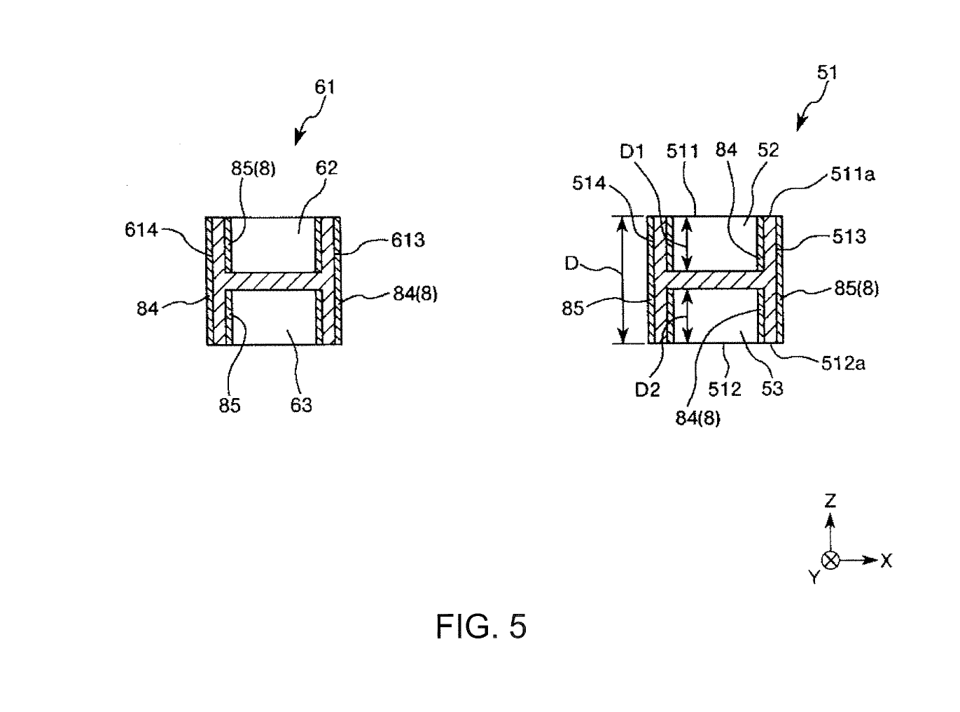

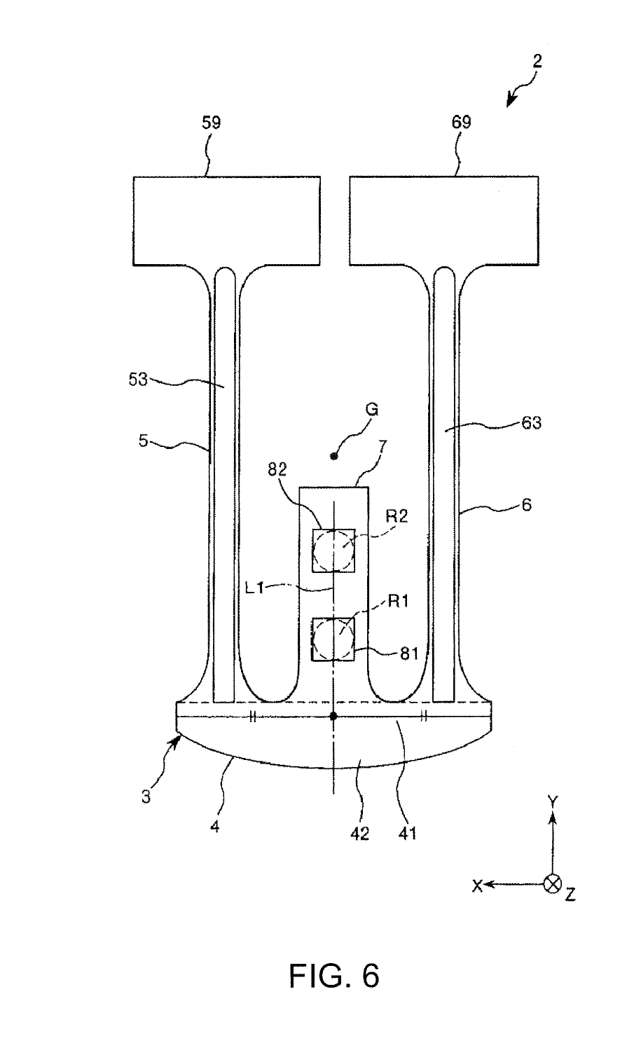

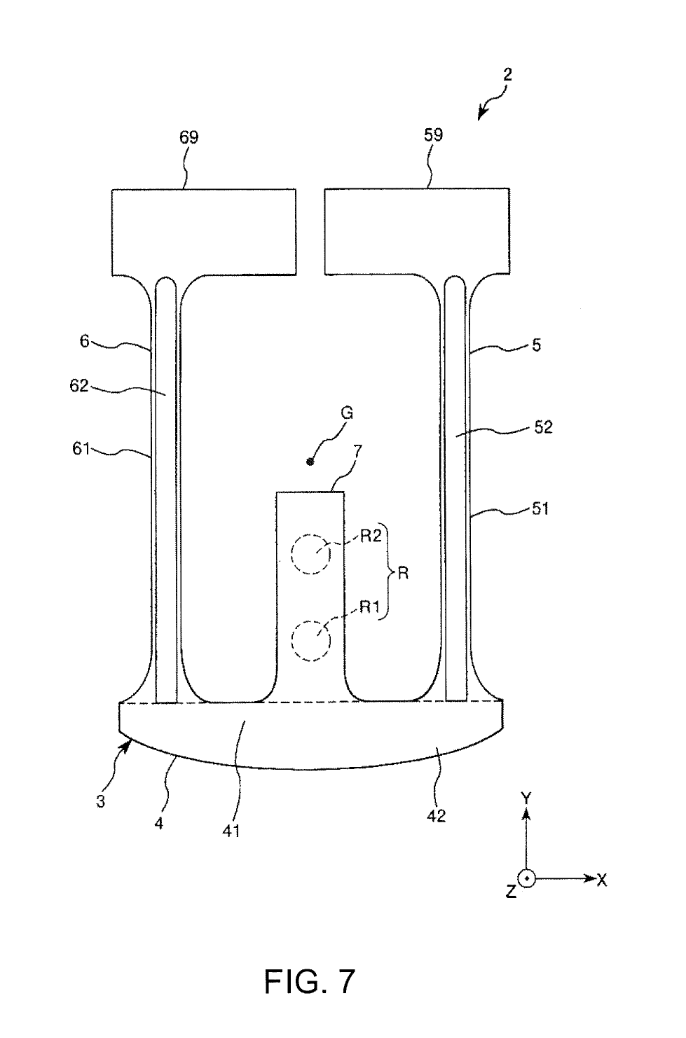

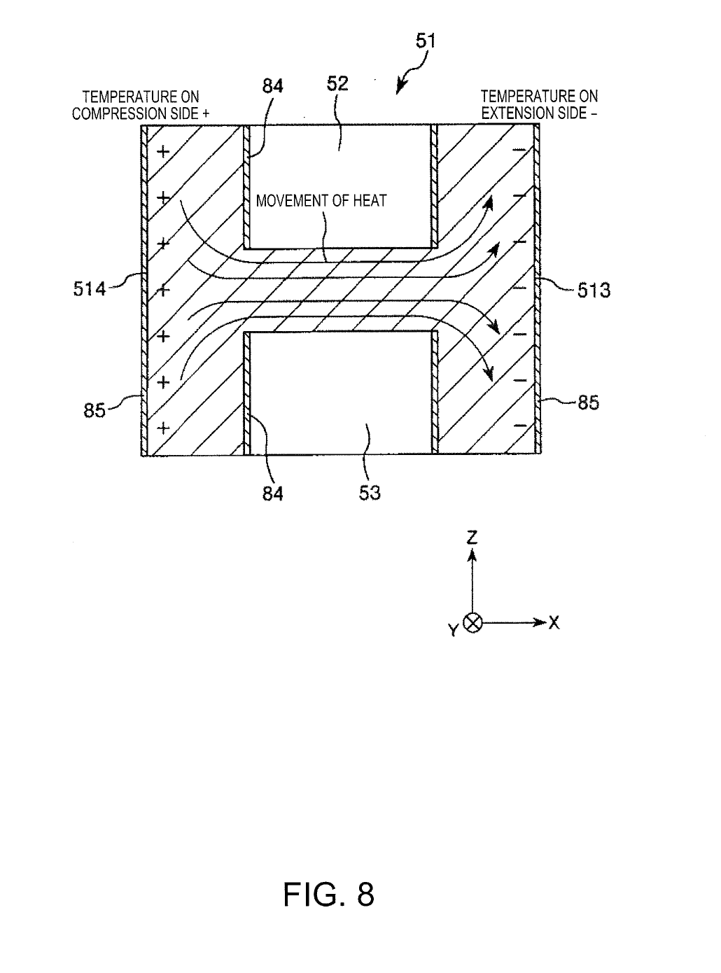

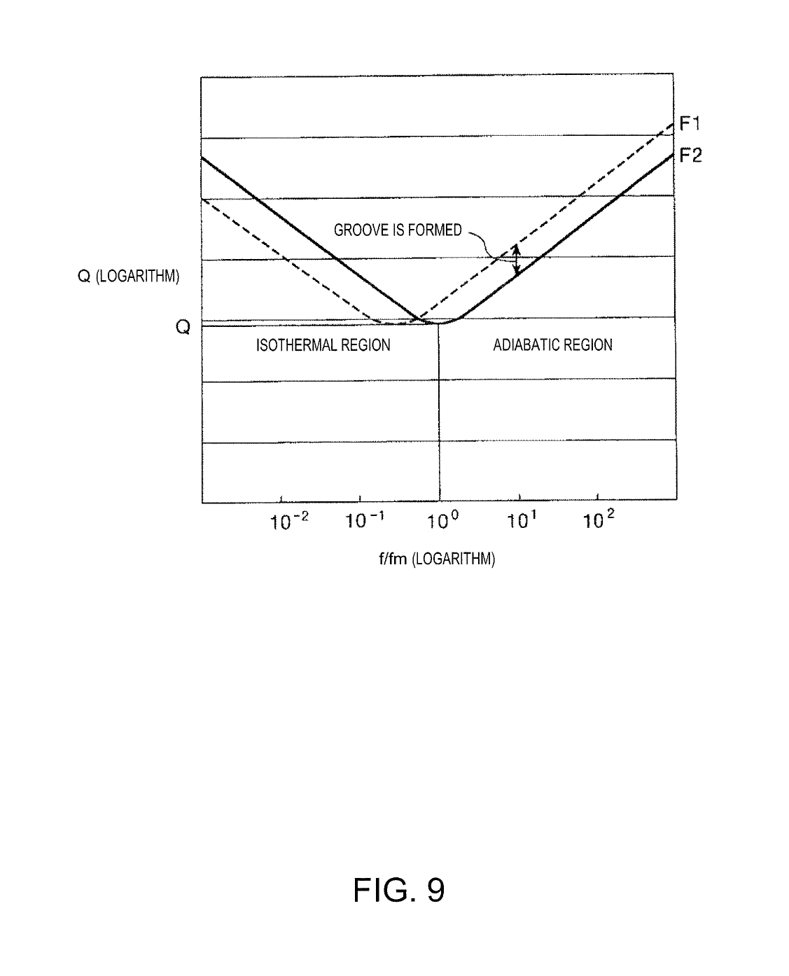

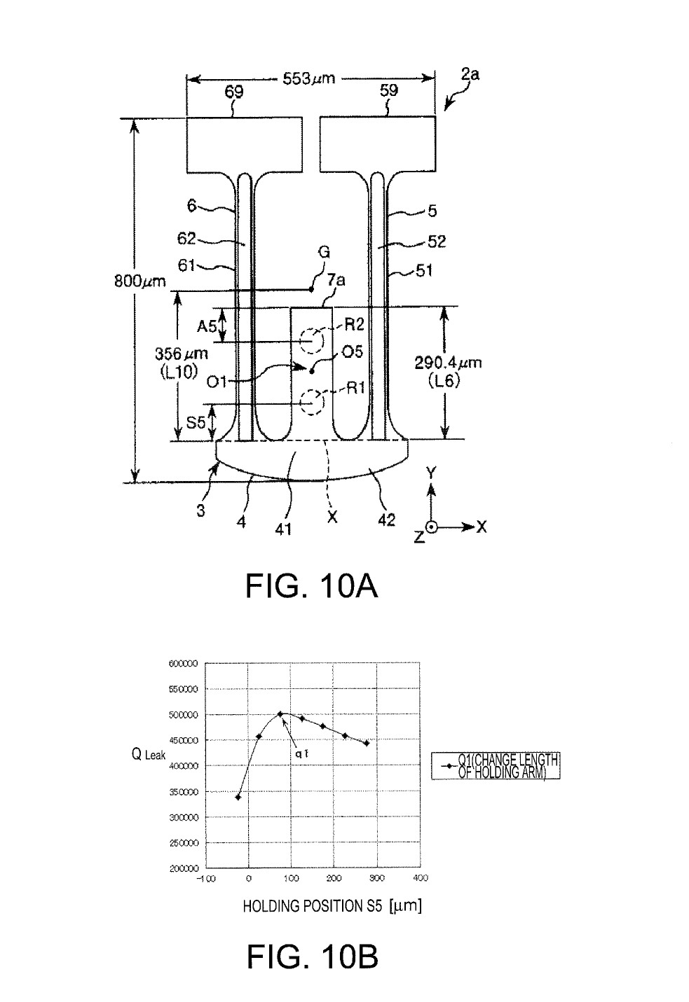

FIG. 1 is a plan view of a resonator according to a first embodiment of the invention. FIG. 2 is a cross-sectional view taken along line A-A of FIG. 1. FIG. 3 is a top view of a resonator element included in the resonator shown in FIG. 1. FIGS. 4A and 4B are plan views illustrating a function of the resonator element shown in FIG. 3. FIG. 5 is a cross-sectional view taken along line B-B of FIG. 3. FIG. 6 is a rear view of the resonator element shown in FIG. 3. FIG. 7 is a top view showing another example of the resonator element shown in FIG. 3. FIG. 8 is a cross-sectional view of a vibrating arm illustrating heat conduction during bending and vibration. FIG. 9 is a graph showing a relationship between a Q value and f/fm. FIG. 10A is a diagram showing an example of a resonator element used in a simulation, and FIG. 10B is a diagram showing a relationship between a holding position of the resonator element and a Q_{Leak} value. Meanwhile, as shown in FIG. 1, three axes perpendicular to each other are assumed to be an X-axis (electrical axis of quartz crystal), a Y-axis (mechanical axis of quartz crystal), and a Z-axis (optical axis of quartz crystal) hereinbelow for convenience of description. In FIG. 2, an upper side is set to a “top (front)” and a lower side is set to a “bottom (back)”. In FIG. 3, an upper side is set to a “distal end” and a lower side is set to a “base end”. Hereinafter, a plan view when seen from a Z-axis direction is simply referred to as a “plan view”.

As shown in FIG. 1, a resonator 1 includes a resonator element (resonator element according to the invention) 2 and a package 9 which accommodates the resonator element 2.

### Package

As shown in FIGS. 1 and 2, the package 9 includes a box-shaped base 91 having a concave portion 911, which is opened on the top surface, and a plate-shaped lid 92 bonded to the base 91 so as to close the opening of the concave portion 911. The package 9 has an accommodation space S formed by closing the concave portion 911 with the lid 92, and the resonator element 2 is accommodated in the accommodation space S in an airtight manner. The accommodation space S may be in a decompressed (preferably, vacuum) state, or may be filled with inert gas such as nitrogen, helium, and argon.

A material of the base 91 is not particularly limited, and various ceramics such as aluminum oxide can be used. In addition, although a material of the lid 92 is not particularly limited, it is preferable to use a member having a linear expansion coefficient similar to that of the material of the base 91. For example, when the above-described ceramic is used as a material of the base 91, it is preferable to use an alloy such as Kovar. Meanwhile, the bonding of the base 91 and the lid 92 is not particularly limited. For example, the base and the lid may be bonded to each other through a metalization layer.

In addition, connecting terminals 951 and 961 are formed on the bottom surface of the concave portion 911 of the base 91. A first conductive adhesive member (fixation member) 11 is provided on the connecting terminal 951, and a second conductive adhesive member (fixation member) 12 is provided on the connecting terminal 961. The resonator element 2 is fixed to the base 91 through the first and second conductive adhesive members 11 and 12. Meanwhile, materials of the first and second conductive adhesive members 11 and 12 are not particularly limited as long as the materials have conductive and adhesive properties. For example, a conductive adhesive member including an epoxy-based, acrylic-based, silicone-based, bismaleimide-based, polyester-based, or polyurethane-based resin mixed with a conductive filler such as silver particles, or a metal bump such as a gold bump, a silver bump, or a copper bump can be used.

In addition, the connecting terminal 951 is electrically connected to an external terminal 953, provided on the bottom surface of the base 91, through a through electrode (not shown) passing through the base 91. Similarly, the connecting terminal 961 is electrically connected to an external terminal 963, provided on the bottom surface of the base 91, through a through electrode (not shown) passing through the base 91. Materials of the connecting terminals 951 and 961, the external terminals 953 and 963, and the through electrode are not particularly limited as long as the materials have conductivity. For example, the terminals and the electrode can be formed of a metal coating in which a coat such as gold (Au), silver (Ag), or copper (Cu) is laminated on a base layer such as chromium (Cr), nickel (Ni), or tungsten (W).

### Resonator Element

As shown in FIGS. 3 to 5, the resonator element 2 includes a quartz crystal substrate 3 and an electrode 8 formed on the quartz crystal substrate 3. Meanwhile, a centroid G of the resonator element 2 is shown in FIG. 3.

The quartz crystal substrate 3 is constituted by a Z-cut quartz crystal plate. The Z-cut quartz crystal plate refers to a quartz crystal substrate having a Z-axis as its thickness direction. Meanwhile, it is preferable that the Z-axis conforms with the thickness direction of the quartz crystal substrate 3. However, from the viewpoint of reducing a change in frequency with temperature near room temperature, the Z-axis may be inclined slightly with respect to the thickness direction.

That is, in a case where the inclination angle is set to θ degrees)(−5°≦θ≦15°, it is assumed that the X-axis of a rectangular coordinate system constituted by the X-axis as the electrical axis of quartz crystal, the Y-axis as the mechanical axis thereof, and the Z-axis as the optical axis thereof is a rotation axis. When an axis obtained by inclining the Z-axis at θ degrees so that a +Z side rotates in the −Y direction of the Y-axis is set to a Z′-axis and an axis obtained by inclining the Y-axis at θ degrees so that a +Y side rotates in the +Z direction of the Z-axis is set to a Y′-axis, the quartz crystal substrate 3 is obtained in which a direction along the Z′-axis is set to the thickness thereof and a surface including the X-axis and the Y′-axis is set to the principal surface thereof.

Meanwhile, the thickness D of the quartz crystal substrate 3 is not particularly limited, but is preferably less than 70 μm. Based on such a numerical range, when the quartz crystal substrate 3 is formed (patterned) by, for example, wet etching, it is possible to effectively prevent unnecessary portions (portions necessary to be removed) from remaining in a boundary between a vibrating arm 5 and a base portion 4, a boundary between an arm portion 51 to be described later and a hammerhead 59 as a weight portion, and the like. For this reason, it is possible to obtain the resonator element 2 capable of effectively reducing vibration leakage. From a different point of view, the thickness D is preferably equal to or greater than 70 μm and equal to or less than 300 μm, and more preferably equal to or greater than 100 μm and equal to or less than 150 μm. Based on such a numerical range, it is possible to form first and second driving electrodes 84 and 85 to be described later to be wide in the side surfaces of the vibrating arm 5 and a vibrating arm 6, and thus it is possible to lower a CI value.

The weight portion is configured as a wide width portion 59 which is larger in length along the X-axis direction than the arm portion 51, but the invention is not limited thereto. The weight portion may have a higher mass density per unit length than that of the arm portion 51. For example, the weight portion may be configured to have a length that is the same as the length of the arm portion along the X-axis direction and to have a thickness along the Z-axis direction which is larger than that of the arm portion. In addition, the weight portion may be configured such that a metal such as Au is provided thickly on the surface of the arm portion which corresponds to the weight portion. Further, the weight portion may be formed of a material having a higher mass density than that of the arm portion.

As shown in FIG. 3, the quartz crystal substrate 3 includes the base portion 4, the pair of vibrating arms (first and second vibrating arms) 5 and 6 extending in the +Y-axis direction (first direction) from the distal end (one end) of the base portion 4, and a supporting arm 7 extending in the +Y-axis direction from the distal end of the base portion 4. The base portion 4, the vibrating arms 5 and 6, and the supporting arm 7 are integrally formed from the quartz crystal substrate 3.

The base portion 4 has a substantially plate shape that extends on the XY plane and has a thickness in the Z-axis direction. The base portion 4 includes a portion (main body 41), which supports and connects the vibrating arms 5 and 6, and a width-decreasing portion 42 to reduce vibration leakage.

The width-decreasing portion 42 is provided on the base end side (side opposite to a side on which the vibrating arms 5 and 6 extend) of the main body 41. In addition, the width (length along the X-axis direction) of the width-decreasing portion 42 gradually decreases as a distance from each of the vibrating arms 5 and 6 increases. Due to the width-decreasing portion 42, it is possible to effectively reduce the vibration leakage of the resonator element 2.

This will be specifically described as follows. Meanwhile, in order to simplify the description, it is assumed that the shape of the resonator element 2 is symmetrical about a predetermined axis parallel to the Y-axis.

First, as shown in FIG. 4A, a case where the width-decreasing portion 42 is not provided will be described. As will be described later, when the vibrating arms 5 and 6 bend and deform so as to separate from each other, displacement close to clockwise rotational movement occurs as indicated by the arrow in the main body 41 in the vicinity to which the vibrating arm 5 is connected, and displacement close to counterclockwise rotational movement occurs as indicated by the arrow in the main body 41 in the vicinity to which the vibrating arm 6 is connected (however, strictly speaking, this movement cannot be said to be rotational movement, and accordingly, this is expressed as “being close to rotational movement” for convenience). Since X-axis direction components of these displacements are in the directions opposite to each other, the X-axis direction components are offset in the X-axis direction central portion of the main body 41, and displacement in the +Y-axis direction remains (however, strictly speaking, displacement in the Z-axis direction also remains, but the displacement in the Z-axis direction will be omitted herein). That is, the main body 41 bends and deforms such that the X-axis direction central portion is displaced in the +Y-axis direction. When a binding material is formed in a supporting arm 7 extending in the +Y-axis direction from the X-axis direction central portion of the main body 41 having the displacement in the +Y-axis direction and is fixed to the package through the binding material, elastic energy due to the displacement in the +Y-axis direction leaks to the outside through the binding material. This is loss of vibration leakage, causing the degradation of the Q value. As a result, the CI value is degraded.

In contrast, as shown in FIG. 4B, when the width-decreasing portion 42 is provided, the width-decreasing portion 42 has an arch-shaped (curved) contour. For this reason, the displacements close to the rotational movement described above are superimposed on each other in the width-decreasing portion 42. That is, in the X-axis direction central portion of the width-decreasing portion 42, displacements in the X-axis direction are offset as in the X-axis direction central portion of the main body 41, and the displacement in the Y-axis direction is also suppressed. In addition, since the contour of the width-decreasing portion 42 has an arch shape, the displacement in the +Y-axis direction that will occur in the main body 41 is also suppressed. As a result, the displacement in the +Y-axis direction of the X-axis direction central portion of the base portion 4 when the width-decreasing portion 42 is provided becomes much smaller than that when the width-decreasing portion 42 is not provided. That is, it is possible to obtain a resonator element having small vibration leakage.

Meanwhile, in this embodiment, although the contour of the width-decreasing portion 42 has an arch shape, the shape of the contour of the width-decreasing portion is not limited thereto as long as the operation described above can be realized. For example, the width-decreasing portion may be a width-decreasing portion having a contour that is formed stepwise by a plurality of straight lines or a width-decreasing portion having a contour that is formed to have a substantially arch shape by a plurality of straight lines.

The vibrating arms 5 and 6 extend in the +Y-axis direction (first direction) from the distal end of the base portion 4 so as to be lined up in the X-axis direction (second direction) and parallel to each other. Each of the vibrating arms 5 and 6 has an elongated shape. The base end of each of the vibrating arms is a fixed end, and the distal end is a free end.

In addition, the vibrating arms 5 and 6 include arm portions 51 and 61 and hammerheads 59 and 69 as weight portions provided at the distal ends of the arm portions 51 and 61. Meanwhile, since the vibrating arms 5 and 6 have the same configuration, the vibrating arm 5 will be described as a representative vibrating arm hereinafter, and description of the vibrating arm 6 will be omitted.

As shown in FIG. 5, the arm portion 51 has a pair of principal surfaces 511 and 512 which are the XY plane, and a pair of side surfaces 513 and 514 which are the YZ plane and connect the pair of principal surfaces 511 and 512 to each other. In addition, the arm portion 51 includes a bottomed groove 52 opened to the principal surface 511 and a bottomed groove 53 opened to the principal surface 512. Each of the grooves 52 and 53 extends in the Y-axis direction, its distal end extends up to the hammerhead 59, and its base end extends up to the base portion 4. In this manner, when the distal end of each of the grooves 52 and 53 extends up to the hammerhead 59, stress concentration occurring near the distal end of each of the grooves 52 and 53 is reduced. Therefore, a possibility of chipping or breakage that occurs when an impact is applied is reduced. In addition, when the base end of each of the grooves 52 and 53 extends up to the base portion 4, stress concentration occurring near the boundary between the vibrating arm 5 and the base portion 4 is reduced. For this reason, for example, a possibility of chipping or breakage that occurs when an impact is applied is reduced.

Although the depth of each of the grooves 52 and 53 is not particularly limited, it is preferable that the relation of 60%≦(D1+D2)/D≦95% is satisfied assuming that the depth of the groove 52 is D1 and the depth of the groove 53 is D2 (in this embodiment, D1=D2). Since a heat transfer path becomes longer by satisfying such a relationship, it is possible to more effectively reduce thermoelastic loss in an adiabatic-like region (to be described later in detail).

Meanwhile, it is preferable to form the grooves 52 and 53 by adjusting the positions of the grooves 52 and 53 in the X-axis direction with respect to the position of the vibrating arm 5 so that the cross-sectional centroid of the vibrating arm 5 matches the center of the cross-sectional shape of the vibrating arm 5. In this manner, since it is possible to reduce an unnecessary vibration (specifically, an oblique vibration having an out-of-plane component) of the vibrating arm 5, it is possible to reduce vibration leakage. In this case, since it is also possible to reduce driving for an unnecessary vibration, a driving region is relatively increased in size. Therefore, it is possible to reduce the CI value.

In addition, assuming that the widths (lengths in the X-axis direction) of bank portions (principal surfaces lined up with the groove 52 interposed therebetween along the width direction perpendicular to the longitudinal direction of the vibrating arm) 511a, which are positioned on both sides of the groove 52 of the principal surface 511 in the X-axis direction, and bank portions 512a, which are positioned on both sides of the groove 53 of the principal surface 512 in the X-axis direction, are W3, it is preferable to satisfy the relation of 0 μm<W3≦20 μm. In this manner, the CI value of the resonator element 2 becomes sufficiently low. In the numerical range described above, it is preferable to satisfy the relation of 5 μm<W3≦9 μm. In this manner, in addition to the effects described above, it is possible to reduce thermoelastic loss. In addition, it is also preferable to satisfy the relation of 0 μm<W3≦5 μm. In this manner, it is possible to further lower the CI value of the resonator element 2.

The hammerhead 59 has a substantially rectangular shape in which the X-axis direction is a longitudinal direction when seen in a plan view. The hammerhead 59 has a width (length in the X-axis direction) which is greater than that of the arm portion 51, and protrudes to both sides in the X-axis direction from the arm portion 51. By forming the hammerhead 59 in such a configuration, it is possible to increase the mass of the hammerhead 59 while suppressing the total length L of the vibrating arm 5. In other words, when the total length L of the vibrating arm 5 is fixed, it is possible to secure the arm portion 51 being as long as possible without reducing the mass effect of the hammerhead 59. For this reason, it is possible to increase the width of the vibrating arm 5 in order to obtain a desired resonance frequency (for example, 32.768 kHz). As a result, since a heat transfer path to be described later becomes longer, thermoelastic loss is reduced and the Q value is improved.

In addition, the center of the hammerhead 59 in the X-axis direction may be slightly shifted from the center of the vibrating arm 5 in the X-axis direction. For example, as shown in FIG. 7, the center of the hammerhead 59 in the X-axis direction may deviate to the supporting arm 7 side with respect to the center of the arm portion 51 in the X-axis direction. In this manner, since the torsion of the vibrating arm 5 is reduced, it is possible to reduce a vibration of the base portion 4 in the Z-axis direction and to further suppress vibration leakage. Meanwhile, the center of the hammerhead 59 in the X-axis direction may deviate to the side opposite to the supporting arm 7 with respect to the center of the arm portion 51 in the X-axis direction.

In addition, when the total length (length in the Y-axis direction) of the vibrating arm 5 is set to L and the length (length in the Y-axis direction) of the hammerhead 59 is set to H, it is preferable that the vibrating arm 5 satisfies the relation of 1.2%<H/L<30.0% and satisfies the relation of 4.6%<H/L<22.3%. When such a numerical range is satisfied, the CI value of the resonator element 2 is low. Therefore, the vibration loss is small, and the resonator element 2 having excellent vibration characteristics is obtained. Here, in this embodiment, the base end of the vibrating arm 5 is set in a position of the line segment, which connects a place where the side surface 514 is connected to the base portion 4 and a place where the side surface 513 is connected to the base portion 4, in the center of the width (length in the X-axis direction) of the vibrating arm 5. In addition, the base end of the hammerhead 59 is set in a position where the width thereof is 1.5 times the width of the arm portion 51, in a tapered portion provided in the distal end of the arm portion 51.

In addition, when the width (length in the X-axis direction) of the arm portion 51 is set to W1 and the width (length in the X-axis direction) of the hammerhead 59 is set to W2, it is preferable that the relation of 1.5≦W2/W1≦10.0 is satisfied, and it is more preferable that the relation of 1.6≦W2/W1≦7.0 is satisfied. By satisfying such a numerical range, it is possible to secure a large width for the hammerhead 59. For this reason, even if the length H of the hammerhead 59 is relatively small as described above, it is possible to sufficiently exhibit the mass effect of the hammerhead 59.

Meanwhile, by setting L≦2 mm, preferably, L≦1 mm, it is possible to obtain a small resonator element used in an oscillator that is mounted in a portable music device, an IC card, and the like. In addition, by setting W1≦100 μm, preferably, W1≦50 μm, it is also possible to obtain a resonator element, which resonates at a low frequency and which is used in an oscillation circuit for realizing low power consumption, in the range of L described above. In addition, in the case of an adiabatic-like region, when the vibrating arms 5 and 6 extend in the Y-axis direction in the quartz crystal Z plate and bend and vibrate in the X direction as in this embodiment, it is preferable that W1≧12.8 μm is satisfied. When the vibrating arms 5 and 6 extend in the X direction in the quartz crystal Z plate and bend and vibrate in the Y direction, it is preferable that W1≧14.4 μm is satisfied. When the vibrating arms 5 and 6 extend in the Y direction in the quartz crystal X plate and bend and vibrate in the Z direction, it is preferable that W1≧15.9 μm is satisfied. In this manner, since an adiabatic-like region can be reliably obtained, thermoelastic loss is reduced by the formation of the grooves 52, 53, 62, and 63, and the Q value is improved. In addition, due to driving in a region where the grooves 52, 53, 62, and 63 are formed, the electric field efficiency is high, and the driving area is secured. Accordingly, the CI value is reduced.

The supporting arm 7 is positioned between the vibrating arms 5 and 6 and extends in the +Y-axis direction from the distal end of the base portion 4. In addition, the distal end of the supporting arm 7 is positioned on the base portion 4 side with respect to the base ends of the hammerheads 59 and 69. In particular, in this embodiment, the distal end of the supporting arm 7 is positioned on the base portion 4 side with respect to the centroid G when seen in a plan view. In addition, the width (length in the X-axis direction) of the supporting arm 7 is substantially constant along the extension direction (Y-axis direction).

Until now, the external form of the quartz crystal substrate 3 has been described. As shown in FIGS. 2, 3, and 6, the quartz crystal substrate 3 has a fixed region R which is provided in one principal surface (principal surface on the −Z-axis side) of the supporting arm 7 and between the centroid G and the base end of the supporting arm 7. The resonator element 2 is fixed to the base 91 (package 9) through the conductive adhesive members 11 and 12 by the fixed region R. In this manner, it is possible to reduce a decrease in the Q value due to the vibration leakage of the resonator element 2. In particular, in this embodiment, since the distal end of the fixed region R (distal end of a second fixation portion R2) is positioned on the base portion 4 side with respect to the centroid G and the base end (base end of a first fixation portion R1) is positioned on the centroid G side with respect to the base end of the supporting arm 7, it is possible to prominently exhibit the effects described above.

The fixed region R has the first fixation portion R1 and the second fixation portion R2 which are spaced apart from each other in the Y-axis direction. The first fixation portion R1 is fixed to the base 91 by the conductive adhesive member 11, and the second fixation portion R2 is fixed to the base 91 by the conductive adhesive member 12. Since the first fixation portion R1 and the second fixation portion R2 are disposed so as to be spaced apart from each other, it is possible to prevent contact (short circuit) between the conductive adhesive members 11 and 12 provided in the fixation portions. Although a separation distance between the first and second fixation portions R1 and R2 is not particularly limited, it is preferable that the distance is, for example, equal to or greater than 20 μm, and it is more preferable that the distance is equal to or greater than 50 μm. In this manner, it is possible to more effectively prevent the contact between the conductive adhesive members 11 and 12.

Meanwhile, an upper limit of the separation distance between the first and second fixation portions R1 and R2 is a value obtained by subtracting the sum of the lengths of the first and second fixation portions R1 and R2 along the Y-axis direction from the length (distance) along the Y-axis direction between the base end (boundary between the supporting arm 7 and the base portion 4) of the supporting arm 7 and the centroid G when seen in a plan view, or a value obtained by subtracting the sum of the lengths of the first and second fixation portions R1 and R2 along the Y-axis direction from the length (distance) along the Y-axis direction of the supporting arm 7 when seen in a plan view.

Meanwhile, the first and second fixation portions R1 and R2 have a circular shape, but the plan-view shapes thereof are not limited thereto. The first and second fixation portions may have an elliptical shape or an oval shape, may have a polygonal shape such as a triangular shape, a quadrangular shape, or a pentagonal shape, or may have an irregular shape. In addition, the diameters of the first and second fixation portions R1 and R2 are not particularly limited, but can be set to, for example, approximately equal to or greater than 60 μm and equal to or less than 100 μm. Thus, it is possible to sufficiently secure contact areas with the conductive adhesive members 11 and 12 and to strongly fix the resonator element 2 to the base 91.

As described above, in the resonator element 2, vibrations of the vibrating arms 5 and 6 are not likely to be transmitted to the supporting arm 7 by the width-decreasing portion 42 of the base portion 4. For this reason, the first and second fixation portions R1 and R2 are provided in the supporting arm 7, and thus it is possible to effectively reduce vibration leakage through the conductive adhesive members 11 and 12.

In addition, the second fixation portion R2 is positioned on the distal end side of the base portion 4 with respect to the first fixation portion R1, and is provided to be parallel to the first fixation portion R1 in the Y-axis direction. In addition, the centers of the first and second fixation portions R1 and R2 are positioned at the center of the supporting arm 7 in the width direction (X-axis direction) and are positioned on a straight line L1 parallel to the Y-axis when seen in a plan view. Thus, it is possible to fix the resonator element 2 to the base 91 in a balanced manner.

As shown in FIG. 3, the fixed region R is configured such that a length (separation distance between a portion of the first fixation portion R1 which is closest to the base end and a portion of the second fixation portion R2 which is closest to the distal end) L5 in the Y-axis direction is greater than a width (length) W5 in the X-axis direction. Thus, since the fixed region R becomes long along the longitudinal direction of the resonator element 2, it is possible to fix the resonator element 2 to the base 91 in a balanced manner. In particular, it is preferable that the length L5 is equal to or greater than twice and equal to or less than five times the width W5. Thus, it is possible to stably fix the resonator element 2 to the base 91.

In addition, when the length (distance) between the centroid G of the resonator element 2 and the base end of the supporting arm 7 (distal end of the base portion 4) is set to L10 when seen in a plan view in the Y-axis direction, the fixed region R is preferably configured such that a center O5 of the fixed region R in the Y-axis direction is positioned in a range O1 of a length of 0.15×L10 to 0.30×L10 toward the distal end from the base end of the supporting arm 7 when seen in a plan view. Since the range O1 is a place which is less likely to be affected by vibrations of the vibrating arms 5 and 6, the fixed region R is disposed centering on this position, and thus it is possible to particularly effectively reduce the vibration leakage through the conductive adhesive members 11 and 12.

The electrode 8 includes a first driving electrode 84, a second driving electrode 85, a first connection electrode 81 connected to the first driving electrode 84, and a second connection electrode 82 connected to the second driving electrode 85.

As shown in FIG. 5, the vibrating arm 5 is provided with a pair of first driving electrodes 84 and a pair of second driving electrodes 85. One of the pair of first driving electrodes 84 is formed on the side surface of the groove 52, and the other is formed on the side surface of the groove 53. In addition, one of the pair of second driving electrodes 85 is formed on the side surface 513, and the other is formed on the side surface 514. Similarly, the vibrating arm 6 is also provided with a pair of first driving electrodes 84 and a pair of second driving electrodes 85. One of the pair of first driving electrodes 84 is formed on a side surface 613, and the other is formed on a side surface 614. In addition, one of the pair of second driving electrodes 85 is formed on the side surface of the groove 62, and the other is formed on the side surface of the groove 63.

In addition, as shown in FIG. 6, the first connection electrode 81 is provided in the first fixation portion R1, and is electrically connected to the first driving electrodes 84 through a wiring not shown in the drawing. In addition, the second connection electrode 82 is provided in the second fixation portion R2, and is electrically connected to the second driving electrodes 85 through a wiring not shown in the drawing. For this reason, the first connection electrode 81 is electrically connected to the connecting terminal 951 through the conductive adhesive member 11, and the second connection electrode 82 is electrically connected to the connecting terminal 961 through the conductive adhesive member 12. When an alternating voltage is applied between the first and second connection electrodes 81 and 82, the vibrating arms 5 and 6 vibrate with a predetermined frequency in an in-plane direction (X-axis direction) so that the vibrating arms alternately repeat mutual approach and separation substantially within a plane. That is, the vibrating arms 5 and 6 vibrate in a so-called X reverse phase mode.

Materials of the first and second driving electrodes 84 and 85 and the first and second connection electrodes 81 and 82 are not particularly limited. The electrodes can be formed of a metal material such as gold (Au), a gold alloy, platinum (Pt), aluminum (Al), an aluminum alloy, silver (Ag), a silver alloy, chromium (Cr), a chromium alloy, nickel (Ni), a nickel alloy, copper (Cu), molybdenum (Mo), niobium (Nb), tungsten (W), iron (Fe), titanium (Ti), cobalt (Co), zinc (Zn), or zirconium (Zr), or a conductive material such as indium tin oxide (ITO).

As specific configurations of the first and second driving electrodes 84 and 85 and the first and second connection electrodes 81 and 82, a configuration can be adopted in which an Au layer of equal to or less than 700 Å is formed on a Cr layer of equal to or less than 700 Å, for example. In particular, since Cr and Au have a great thermoelastic loss, the Cr layer and the Au layer are preferably set to equal to or less than 200 Å. When insulation breakdown resistance is increased, the Cr layer and the Au layer are preferably set to equal to or greater than 1000 Å. Further, since Ni has a thermal expansion coefficient close to that of quartz crystal, thermal stress caused by electrodes is reduced by using a Ni layer as a foundation layer in place of the Cr layer, and thus it is possible to obtain a resonator element with a good long-term reliability (aging characteristics).

Meanwhile, the hammerheads 59 and 69 as weight portions are configured as wide width portions of which the lengths along the X-axis direction are longer than those of the arm portions 51 and 61. However, the invention is not limited thereto, and the mass density per unit length of the hammerheads may be greater than those of the arm portions 51 and 61. For example, the weight portion may be configured to have a length that is the same as the lengths along the X-axis direction of the arm portions 51 and 61 and to have a thickness along the Z-axis direction which is larger than those of the arm portions. In addition, the weight portion may be configured such that a metal such as Au is provided thickly on the surfaces of the arm portions 51 and 61 which correspond to the weight portion. Further, the weight portion may be formed of a material having a higher mass density than those of the arm portions 51 and 61.

Until now, the resonator element 2 has been described. As described above, in the resonator element 2, the grooves 52 and 53 and the grooves 62 and 63 are formed in the vibrating arm 5 and the vibrating arm 6 to reduce thermoelastic loss. Hereinafter, this will be described concretely below by using the vibrating arm 5 as an example.

As described above, the vibrating arm 5 bends and vibrates substantially in the in-plane direction by applying an alternating voltage between the first and second driving electrodes 84 and 85. As shown in FIG. 8, at the time of the bending and vibration of the vibrating arm, the side surface 514 expands when the side surface 513 of the arm portion 51 contracts. In contrast, the side surface 514 contracts when the side surface 513 expands. When the vibrating arm 5 does not cause the Gough-Joule effect (when energy elasticity is dominant over the entropy elasticity), the temperature on the contracted surface side of the side surfaces 513 and 514 rises, and the temperature on the expanded surface side thereof drops. For this reason, a difference in temperature occurs between the side surface 513 and the side surface 514, in other words, inside the arm portion 51. Due to heat conduction resulting from the difference in temperature, loss of vibration energy occurs. As a result, the Q value of the resonator element 2 is reduced. The reduction in the Q value is also referred to as a thermoelastic effect, and the loss of energy due to the thermoelastic effect is also referred to as thermoelastic loss.

In a resonator element that vibrates in a bending vibration mode and has the same configuration as the resonator element 2, when a bending vibration frequency (mechanical bending vibration frequency) f of the vibrating arm 5 changes, the Q value is minimized when the bending vibration frequency of the vibrating arm 5 conforms with a thermal relaxation frequency fm. The thermal relaxation frequency fm can be calculated by an expression of fm=1/(2πτ) (where, in the expression, π denotes the circular constant, and τ denotes a relaxation time required for a difference in temperature to become e₋₁ times by heat conduction, assuming that e is Napier's constant).

In addition, if a thermal relaxation frequency of a flat plate structure (structure having a rectangular cross-sectional shape) is fm0, fm0 can be calculated by the following expression.

fm0=πk/(2ρCpa²) (1)

Meanwhile, π is the circular constant, k is the thermal conductivity of the vibrating arm 5 in the vibration direction (X-axis direction), ρ is the mass density of the vibrating arm 5, Cp is the heat capacity of the vibrating arm 5, and a is the width of the vibrating arm 5 in the vibration direction. When the constants of the material itself (that is, quartz crystal) of the vibrating arm 5 are input as the thermal conductivity k, the mass density ρ, and the heat capacity Cp in Expression (1), the calculated thermal relaxation frequency fm0 is a value when the grooves 52 and 53 are not provided in the vibrating arm 5.

In the vibrating arm 5, the grooves 52 and 53 are formed so as to be positioned between the side surfaces 513 and 514. For this reason, since a heat transfer path for balancing a difference in temperature between the side surfaces 513 and 514, which is caused when the vibrating arm 5 bends and vibrates, is formed by heat conduction so as to bypass the grooves 52 and 53, the heat transfer path thus becomes longer than a straight-line distance (shortest distance) between the side surfaces 513 and 514. Therefore, the relaxation time τ becomes longer and the thermal relaxation frequency fm becomes lower, as compared with a case where the grooves 52 and 53 are not provided in the vibrating arm 5.

FIG. 9 is a graph showing the f/fm dependence of the Q value of the resonator element in the bending vibration mode. In FIG. 9, a curve F1 shown by a dotted line indicates a case where a groove is formed in a vibrating arm as in the resonator element 2, and a curve F2 shown by a solid line indicates a case where a groove is not formed in a vibrating arm. As shown in FIG. 9, the shapes of the curves F1 and F2 are not changed, but the curve F1 is shifted in a frequency decrease direction with respect to the curve F2 in association with a reduction in the thermal relaxation frequency fm mentioned above. Accordingly, assuming that the thermal relaxation frequency when a groove is formed in a vibrating arm as in the resonator element 2 is fm1, the Q value of the resonator element in which a groove is formed in the vibrating arm is always higher than the Q value of the resonator element in which a groove is not formed in the vibrating arm by the following Expression (2) being satisfied.

f>\sqrt{fₘ₀fₘ₁} (2)

Further, it is possible to obtain a higher Q value when being limited to the relation of f/fm0>1.

Meanwhile, in FIG. 9, the region of f/fm<1 is also referred to as an isothermal-like region. In this isothermal-like region, the Q value increases as f/fm decreases. This is because the above-described difference in temperature within the vibrating arm is not likely to occur as the mechanical frequency of the vibrating arm becomes low (vibration of the vibrating arm becomes slow). Accordingly, at a limit when f/fm approaches infinitely 0 (zero), an isothermal quasi-static operation is realized, and thus thermoelastic loss approaches infinitely 0 (zero). On the other hand, the region of f/fm>1 is also referred to as an adiabatic-like region. In this adiabatic-like region, the Q value increases as f/fm increases. This is because the switching of temperature rise and temperature effect of each side surface becomes fast as the mechanical frequency of the vibrating arm becomes high, and accordingly, there is no time in which the above-described heat conduction occurs. Accordingly, at a limit when f/fm is increased to approaching infinity, an adiabatic operation is realized, and thus thermoelastic loss approaches infinitely 0 (zero). In other words, from this, f/fm is in the adiabatic-like region if the relation of f/fm>1 is satisfied.

Here, since the materials (metal materials) of the first and second driving electrodes 84 and 85 have higher thermal conductivity than quartz crystal which is the material of the vibrating arms 5 and 6, heat conduction through the first driving electrode 84 is actively performed in the vibrating arm 5 and heat conduction through the second driving electrode 85 is actively performed in the vibrating arm 6. When such heat conduction through the first and second driving electrodes 84 and 85 is actively performed, the relaxation time τ is shortened. Consequently, as shown in FIG. 5, the first driving electrode 84 is divided into the side surface 513 side and the side surface 514 side at the bottom surfaces of the grooves 52 and 53 in the vibrating arm 5, and the second driving electrode 85 is divided into the side surface 613 side and the side surface 614 side at the bottom surfaces of the grooves 62 and 63 in the vibrating arm 6, thereby reducing the above-described heat conduction. As a result, it is possible to prevent the relaxation time τ from being shortened, and thus the resonator element 2 having a higher Q value is obtained.

Next, vibration characteristics of the resonator element 2 will be described on the basis of simulation results.

FIG. 10A shows an example of a resonator element 2a used in this simulation. As shown in FIG. 10A, in this simulation, the resonator element 2a having the total length (length in the Y-axis direction) of 800 μm, the width (length in the X-axis direction) of 553 μm, and the thickness (thickness in the Z-axis direction) of 130 μm, and including the grooves 52, 53, 62, and 63 having a depth of 60 μm is used. In addition, a separation distance between the centroid G thereof and a base end X of the supporting arm 7 is 356 μm.

In the resonator element 2a shown in FIG. 10A, the distal end of a supporting arm 7a is positioned on the base portion 4 side with respect to the centroid G, and the length of the supporting arm 7a in the Y-axis direction is 290.4 μm. In addition, the center O5 of a fixation portion R is positioned within the range O1 in the Y-axis direction between the centroid G and the base end X of the supporting arm 7a. In addition, a distance (holding position S5) between the base end X of the supporting arm 7a and the central portion of the first fixation portion R1 is 76 μm, and a separation distance A5 between the distal end of the supporting arm 7a and the central portion of the second fixation portion R2 is 84.4 μm. In addition, the first and second fixation portions R1 and R2 have a circular shape and have a diameter of 80 μm.

Consideration is given to simulating vibration characteristics of the resonator element 2 in a state in which the resonator element 2a is fixed to an object by the first and second fixation portions R1 and R2 by using a gold bump (having a Young's modulus of 70.0 [GPa], a Poisson's ratio of 0.44, a mass density of 19300 [kg/m³], a diameter of 80 μm, and a thickness of 20 μm). Meanwhile, the object having the same physical properties as the package 9 is used. Regarding elastic waves reaching an interface between the first and second fixation portions R1 and R2 and the object, assuming that the elastic waves transmitting the object leak as they are and are not returned and that energy loss corresponding to the leakage is vibration leakage, a Q value taking only the vibration leakage into consideration is calculated.

A graph Q1 shown in FIG. 10B shows results obtained by simulating vibration characteristics of the resonator element 2. In FIG. 10B, a horizontal axis represents the holding position S5 of the first fixation portion R1, and a vertical axis represents a Q_{Leak} value. Meanwhile, the Q_{Leak} value is an index of the Q value (that is, Q value that does not take thermoelastic loss and the like into consideration) which takes only vibration leakage into consideration, and indicates that the vibration characteristics improve as the value increases.

In addition, the graph Q1 shown in FIG. 10B shows simulation results based on the above-described resonator element 2a shown in FIG. 10A. Meanwhile, a plot q1 on the graph Q1 is equivalent to the resonator element 2a.

The graph Q1 shown in FIG. 10B shows simulation results when a length L6 of the supporting arm 7a in the Y-axis direction is changed in a state where the separation distance A5 between the distal end of the supporting arm 7a and the second fixation portion R2 is made constant. That is, the graph Q1 shows changes in the Q_{Leak} value of the resonator element 2a when the holding position S5 of the first fixation portion R1 is changed by changing the length L6 to thereby change the position where the fixed region R is disposed, in a state where the separation distance A5 is made constant.

According to the graph Q1, the Q_{Leak} value is highest in the case of the plot q1, the Q_{Leak} value is rapidly lowered as the holding position S5 becomes lower than that in the plot q1, and the Q_{Leak} value is gently lowered as the holding position S5 becomes higher than that in the plot q1.

From the results, it may be said that the resonator element 2a shown in FIG. 10A, that is, the resonator element 2a in which the fixed region R is positioned in the range O1 in the Y-axis direction between the centroid G and the base end of the supporting arm 7a and the center O5 of the fixed region R in the Y-axis direction is positioned in the vicinity of the center in the Y-axis direction between the centroid G and the base end of the supporting arm 7a has the highest Q_{Leak} value.

For this reason, when the fixed region R is disposed centering on this position, it is possible to particularly effectively reduce the reduction in the Q value due to the vibration leakage of the resonator element 2a. In addition, providing of the fixed region R between the centroid G and the base end X of the supporting arm 7a can make being affected by vibration occurring when the vibrating arms 5 and 6 bend and deform more difficult.

Incidentally, vibration characteristics of the resonator element 2 may be simulated in a state where the resonator element 2a is fixed to an object using a bismaleimide-based conductive adhesive member (having a Young's modulus of 3.4 [GPa], a Poisson's ratio of 0.33, amass density of 4070 [kg/m³], a diameter of 80 μm, and a thickness of 20 μm) in place of the above-described gold bump. Even in this case, it is possible to obtain the same effects as in the case where the above-described gold bump is used.

### Second Embodiment

Next, a resonator according to a second embodiment of the invention will be described.

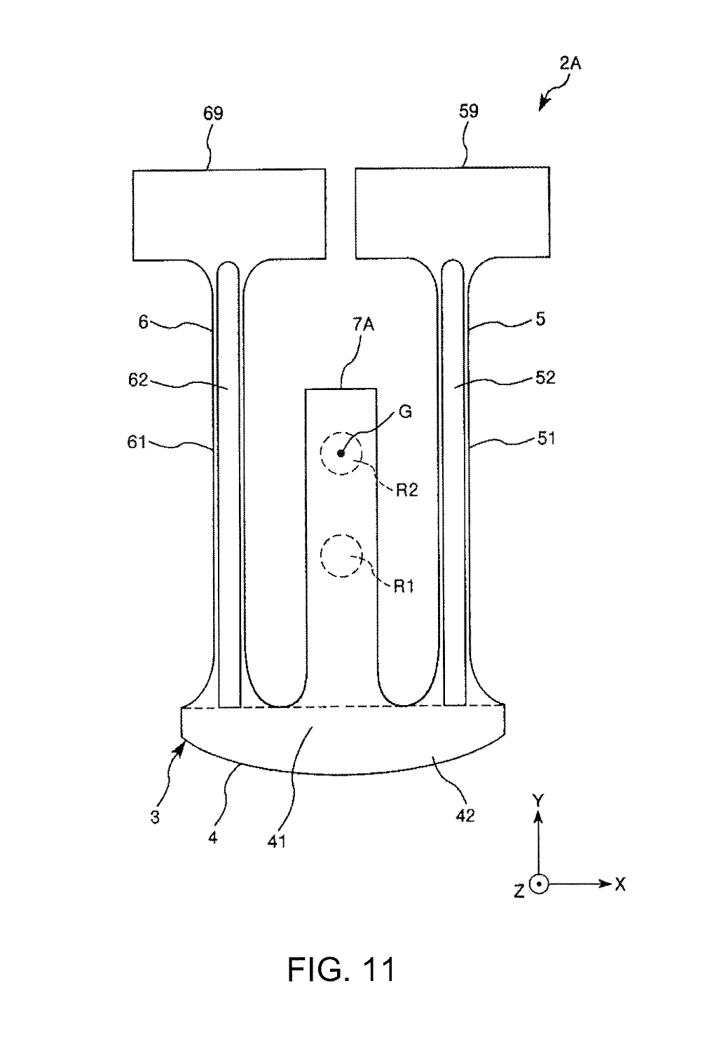

FIG. 11 is a top view of a resonator element included in the resonator according to the second embodiment of the invention.

Hereinafter, the resonator according to the second embodiment will be described focusing on the differences from the first embodiment described above, and a description of the same matters will be omitted.

The resonator according to the second embodiment of the invention is the same as that of the first embodiment described above except that the configuration of a resonator element is different. Meanwhile, the same components as in the first embodiment described above are denoted by the same reference numerals.

As shown in FIG. 11, a supporting arm 7A of a resonator element 2A is provided over a centroid G. That is, the supporting arm 7A is larger in length in the Y-axis direction than the supporting arm 7 of the first embodiment described above. A fixed region R is provided on the distal end side of the supporting arm 7A. In addition, a second fixation portion R2 is provided at a position overlapping the centroid G when seen in a plan view from the Z-axis direction. Meanwhile, a positional relationship between the distal end of the supporting arm 7A and the fixed region R (first and second fixation portions R1 and R2) is the same as the positional relationship between the supporting arm 7 and the fixed region R of the first embodiment described above.

Also in the second embodiment, the same effects as in the first embodiment described above can be exhibited.

### Third Embodiment

Next, a resonator according to a third embodiment of the invention will be described.

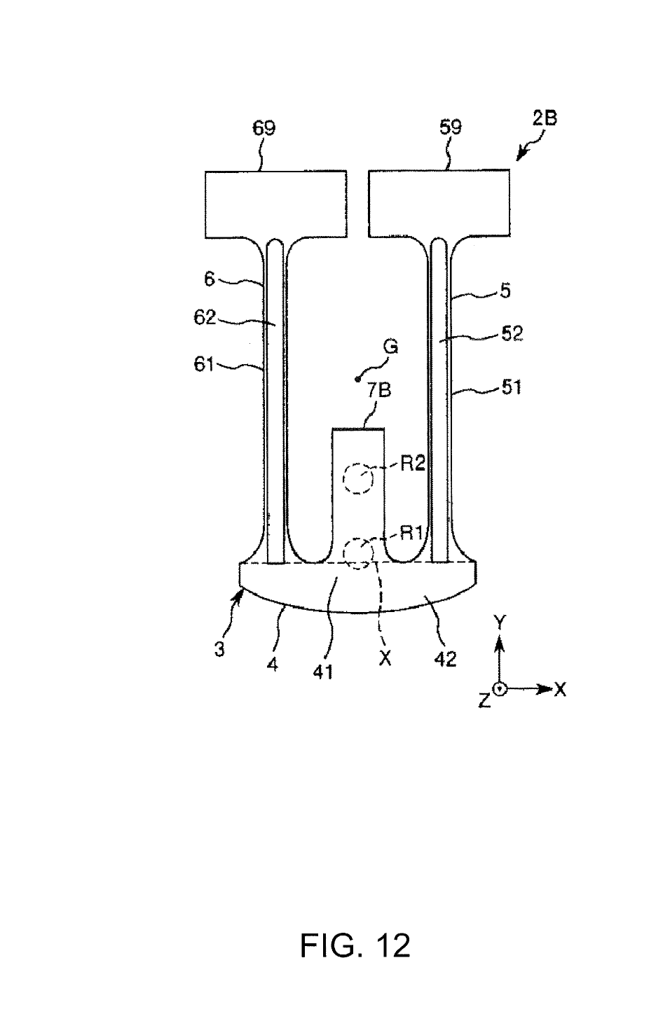

FIG. 12 is a top view of a resonator element included in the resonator according to the third embodiment of the invention.

Hereinafter, the resonator according to the third embodiment will be described focusing on the differences from the first embodiment described above, and a description of the same matters will be omitted.

The resonator according to the third embodiment of the invention is the same as that of the first embodiment described above except that the configuration of a resonator element is different. Meanwhile, the same components as in the first embodiment described above are denoted by the same reference numerals.

As shown in FIG. 12, a distal end of a supporting arm 7B of a resonator element 2B is positioned on a base portion 4 side with respect to the distal end of the supporting arm 7 of the first embodiment. That is, the supporting arm 7B is smaller in length in the Y-axis direction than the supporting arm 7 of the first embodiment. In addition, a fixation portion R is provided so as to be biased to the base end side of the supporting arm 7B. Meanwhile, a positional relationship between the distal end of the supporting arm 7B and the fixed region R (first and second fixation portions R1 and R2) is the same as the positional relationship between the supporting arm 7 and the fixed region R of the first embodiment described above. In addition, the base end side of the first fixation portion R1 is positioned at the base portion 4 across the base end of the supporting arm 7B when seen in a plan view from the Z-axis direction. That is, the first fixation portion R1 is provided over a boundary between the supporting arm 7B and the base portion 4. Here, in this embodiment, the base end of the supporting arm 7B, that is, a boundary between the supporting arm 7B and the base portion 4 is set to a line segment that connects places where both side surfaces of the supporting arm 7B are connected to the base portion 4, and is shown by a dashed line X in FIG. 12.

Also in the third embodiment, the same effects as in the first embodiment described above can be exhibited.

### Fourth Embodiment

Next, a resonator according to a fourth embodiment of the invention will be described.

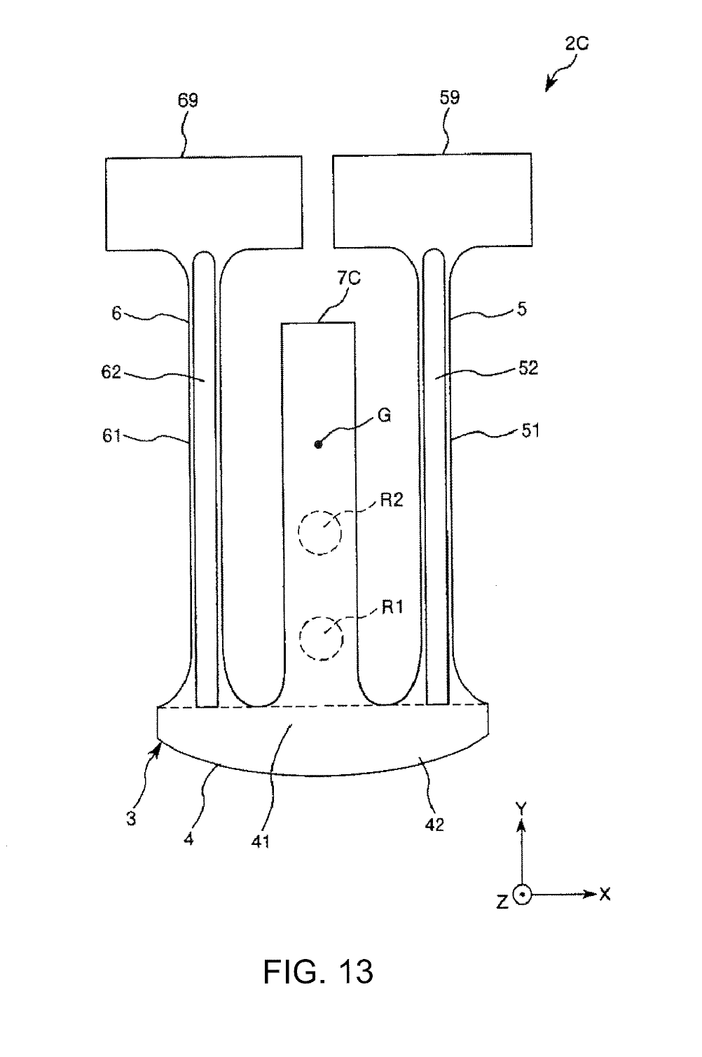

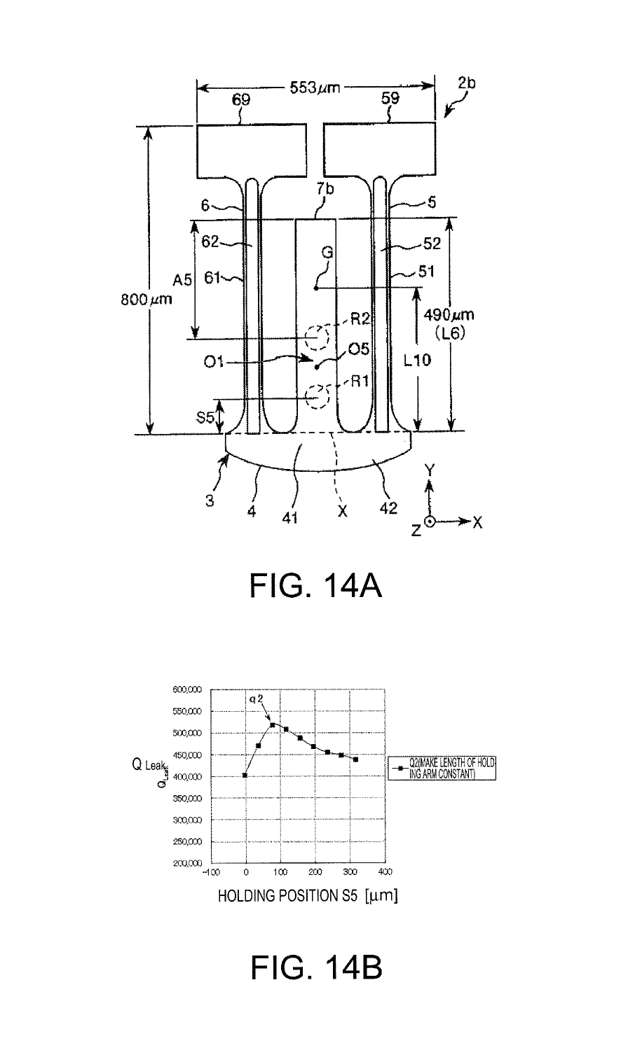

FIG. 13 is a top view of a resonator element included in the resonator according to the fourth embodiment of the invention. FIG. 14A is a diagram showing an example of a resonator element used in a simulation, and FIG. 14B is a diagram showing a relationship between a holding position of the resonator element and a Q_{Leak} value.

Hereinafter, the resonator according to the fourth embodiment will be described focusing on the differences from the first embodiment described above, and a description of the same matters will be omitted.

The resonator according to the fourth embodiment of the invention is the same as that of the first embodiment described above except that the configuration of a resonator element is different. Meanwhile, the same components as in the first embodiment described above are denoted by the same reference numerals.

As shown in FIG. 13, a supporting arm 7C of a resonator element 2C is provided over a centroid G when seen in a plan view, the base end of the supporting arm 7C is positioned on the −Y-axis side with respect to the centroid, and the distal end of the supporting arm 7C is positioned on the +Y-axis side with respect to the centroid G. That is, the total length (length in the Y-axis direction) of the supporting arm 7C is larger than that of the supporting arm 7 of the first embodiment described above. A fixed region R is provided on the base end side of the supporting arm 7C. Meanwhile, a positional relationship between the base end of the supporting arm 7C and the fixed region R (first and second fixation portions R1 and R2) is the same as the positional relationship between the supporting arm 7 and the fixed region R of the first embodiment described above.

Here, similarly to the resonator element 2 of the first embodiment, the resonator element 2C is configured so as to vibrate in an X reverse phase mode in which vibrating arms 5 and 6 bend and vibrate by alternately repeating mutual approach and separation. In addition to the vibration mode, there are unnecessary vibration modes such as an X common mode in which the vibrating arms 5 and 6 bend and vibrate to the same side in the X-axis direction, a Z common mode in which the vibrating arms 5 and 6 bend and vibrate to the same side in the Z-axis direction, a Z reverse phase mode in which the vibrating arms 5 and 6 bend and vibrate to opposite sides of the Z-axis, a torsional common mode in which the vibrating arms 5 and 6 are twisted and vibrate in the same direction about the Y-axis, and a torsional reverse phase mode in which the vibrating arms 5 and 6 are twisted and vibrate in opposite directions about the Y-axis. When the resonator element 2C vibrates in the X reverse phase mode, the supporting arm 7C alternately vibrates in the +Y-axis direction and the −Y-axis direction, as described above. However, when the resonator element 2C has an asymmetrical shape and when the resonator element is combined with an unnecessary mode, the distal end of the supporting arm 7C involuntarily vibrates in the X-axis direction (in-plane direction) and the Z-axis direction (out-plane direction). For this reason, as in this embodiment, the fixed region R is provided on the base end side by avoiding the distal end of the supporting arm 7C, and thus it is possible to further reduce vibration leakage.

In this embodiment, as compared with the first embodiment, the mass increases due to the large length of the supporting arm 7C, and the supporting arm is not likely to vibrate to that extent. In addition, it is possible to provide the fixed region R in a place (the base end side of the supporting arm 7C) which is further spaced from the distal end of the supporting arm 7C. Thus, since the fixed region R is less likely to be affected by vibration of the vibrating arms 5 and 6 described above, it is possible to particularly effectively reduce vibration leakage as compared with the first embodiment.

Also in the fourth embodiment, the same effects as in the first embodiment described above can be exhibited.

In addition, vibration characteristics of the resonator element 2 described above will be described below on the basis of simulation results.

FIG. 14A shows an example of a resonator element 2b using this simulation. As shown in FIG. 14A, in this simulation, the resonator element 2b having the total length (length in the Y-axis direction) of 800 μm, the width (length in the X-axis direction) of 553 μm, and the thickness (thickness in the Z-axis direction) of 130 μm, and including grooves 52, 53, 62, and 63 having a depth of 60 μm is used. In addition, a separation distance between the centroid G thereof and a base end X of a supporting arm 7b is 356 μm.

In the resonator element 2b shown in FIG. 14A, the supporting arm 7b is provided over the centroid G when seen in a plan view. In addition, the length of the supporting arm 7b in the Y-axis direction is 490 μm. In addition, a center O5 of the fixed region R is positioned within a range O1 in the Y-axis direction between the centroid G and the base end X of the supporting arm 7b. In addition, a distance (holding position S5) between the base end X of the supporting arm 7b and the central portion of the first fixation portion R1 is 76 μm, and a separation distance between the distal end of the supporting arm 7b and the second fixation portion R2 is 84.4 μm. In addition, the first and second fixation portions R1 and R2 have a circular shape and have a diameter of 80 μm.

Consideration is given to simulating vibration characteristics of the resonator element 2 in a state in which the resonator element 2b is fixed to an object by the first and second fixation portions R1 and R2 by using a gold bump (having a Young's modulus of 70.0 [GPa], a Poisson's ratio of 0.44, a mass density of 19300 [kg/m³], a diameter of 80 μm, and a thickness of 20 μm). Meanwhile, the object having the same physical properties as a package 9 is used.

A graph Q2 shown in FIG. 14B shows results obtained by simulating vibration characteristics of the resonator element 2b. In FIG. 14B, a horizontal axis represents the holding position S5 of the first fixation portion R1, and a vertical axis represents a Q_{Leak} value. Meanwhile, the Q_{Leak} value is an index of the Q value (that is, Q value that does not take thermoelastic loss and the like into consideration) which takes only vibration leakage into consideration, and indicates that the vibration characteristics improve as the value increases.

In addition, the graph Q2 shown in FIG. 14B shows simulation results based on the above-described resonator element 2b shown in FIG. 14A. Meanwhile, a plot q2 on the graph Q2 is equivalent to the resonator element 2b.

The graph Q2 shown in FIG. 14B shows simulation results when the position of the fixed region R is changed in a state where the distal end of the supporting arm 7b passes across the centroid G when seen in a plan view and a length L6 of the supporting arm 7b in the Y-axis direction is made constant. That is, the graph Q2 shows changes in the Q_{Leak} value when the holding position S5 of the first fixation portion R1 is changed by changing the position of the fixed region R in a state where the length L6 of the supporting arm 7b is made constant.

According to the graph Q2, the Q_{Leak} value is highest in the case of the plot q2, the Q_{Leak} value is rapidly lowered as the holding position S5 becomes lower than that in the plot q2, and the Q_{Leak} value is gently lowered as the holding position S5 becomes higher than that in the plot q2.

From the results, it may be said that the resonator element 2b shown in FIG. 14A, that is, the resonator element 2b in which the fixed region R is positioned in the range O1 in the Y-axis direction between the centroid G and the base end of the supporting arm 7a and the center O5 of the fixed region R in the Y-axis direction is positioned in the vicinity of the center in the Y-axis direction between the centroid G and the base end of the supporting arm 7a has the highest Q_{Leak} value.

For this reason, when the fixed region R is disposed centering on this position, it is possible to particularly effectively reduce the reduction in the Q value due to the vibration leakage of the resonator element 2b. In addition, providing of the fixed region R between the centroid G and the base end X of the supporting arm 7 can make being affected by vibration occurring when the vibrating arms 5 and 6 bend and deform more difficult.

In addition, as in the simulation results of this embodiment, it is possible to obtain a higher Q_{Leak} value when the position of the fixed region R is changed in a state where the distal end of the supporting arm 7b passes across the centroid G when seen in a plan view and the length L6 is made constant, with respect to when the length L6 is changed in a state where the separation distance A5 is made constant as shown in the first embodiment. For this reason, it is possible to particularly effectively reduce vibration leakage as compared with the first embodiment. It is considered that this is because, as compared with the first embodiment, the mass increases due to the large length of the supporting arm 7C, and the supporting arm 7C is not likely to vibrate to that extent.

### Fifth Embodiment

Next, a resonator according to a fifth embodiment of the invention will be described.

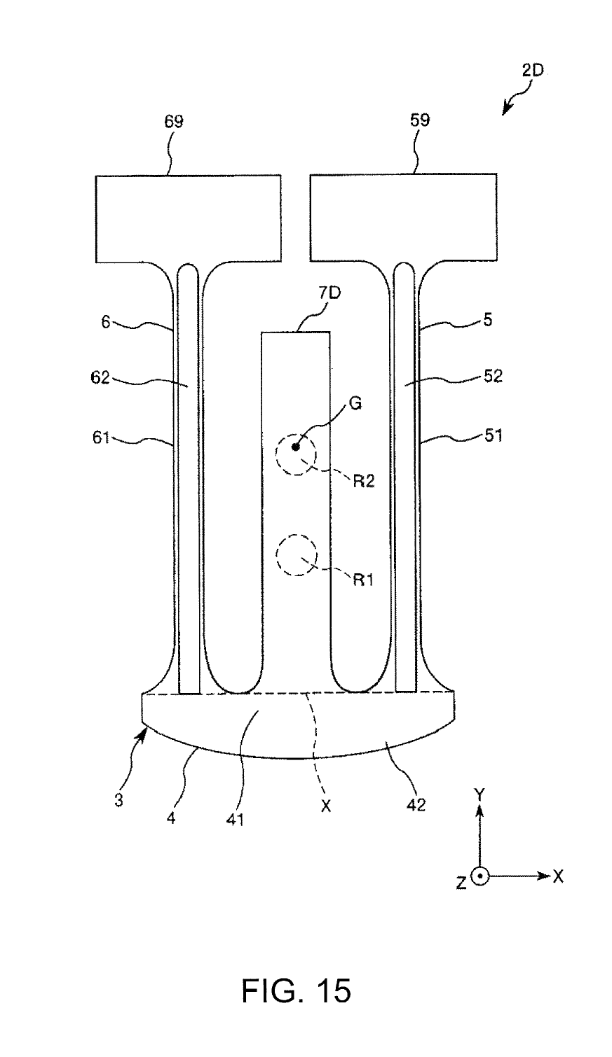

FIG. 15 is a top view of a resonator element included in the resonator according to the fifth embodiment of the invention.

Hereinafter, the resonator according to the fifth embodiment will be described focusing on the differences from the first embodiment described above, and a description of the same matters will be omitted.

The resonator according to the fifth embodiment of the invention is the same as that of the first embodiment described above except that the configuration of a resonator element is different. Meanwhile, the same components as in the first embodiment described above are denoted by the same reference numerals.

As shown in FIG. 15, a supporting arm 7D of a resonator element 2D is provided over a centroid G. That is, the supporting arm 7D is larger in length in the Y-axis direction than the supporting arm 7 of the first embodiment described above. A fixed region R is provided in the vicinity of the central portion of the supporting arm 7D. In addition, a second fixation portion R2 is provided at a position overlapping the centroid G when seen in a plan view from the Z-axis direction. Meanwhile, a positional relationship between a first fixation portion R1 and the second fixation portion R2 is the same as the positional relationship between the first and second fixation portions R1 and R2 of the first embodiment described above.

Here, similarly to the resonator element 2 of the first embodiment described above, the resonator element 2D is configured so as to vibrate in an X reverse phase mode. However, a combination of the vibration mode and another unnecessary vibration mode leads to an imbalance in vibrating arms 5 and 6, and thus the distal end of the supporting arm 7D involuntarily vibrates in the X-axis direction and the Z-axis direction. For this reason, similarly to the fourth embodiment described above, also in this embodiment, the fixed region R is provided by avoiding the distal end of the supporting arm 7D, and thus it is possible to further reduce vibration leakage.

Similarly to the first embodiment described above, in the resonator element 2D, vibrations of the vibrating arms 5 and 6 are offset by a width-decreasing portion 42, and thus are not likely to be transmitted to the supporting arm 7D. However, the vibration that cannot be wholly offset by the width-decreasing portion 42 may be transmitted to the supporting arm 7D through a base portion 4. For this reason, in this embodiment, the fixed region R is provided by avoiding the base end of the supporting arm 7D. Thus, it is possible to further reduce vibration leakage.

Meanwhile, a length L5 of the fixed region R is not particularly limited. However, when a separation distance (length in the Y-axis direction) between the centroid G and a base end (boundary) X of the supporting arm 7D is set to L10, it is preferable that the relation of 0.589×L10≦L5≦L10 is satisfied. Thus, it is possible to more reliably reduce a reduction in a Q value due to vibration leakage.

Also in the fifth embodiment, the same effects as in the first embodiment described above can be exhibited.

### Sixth Embodiment

Next, a resonator according to a sixth embodiment of the invention will be described.

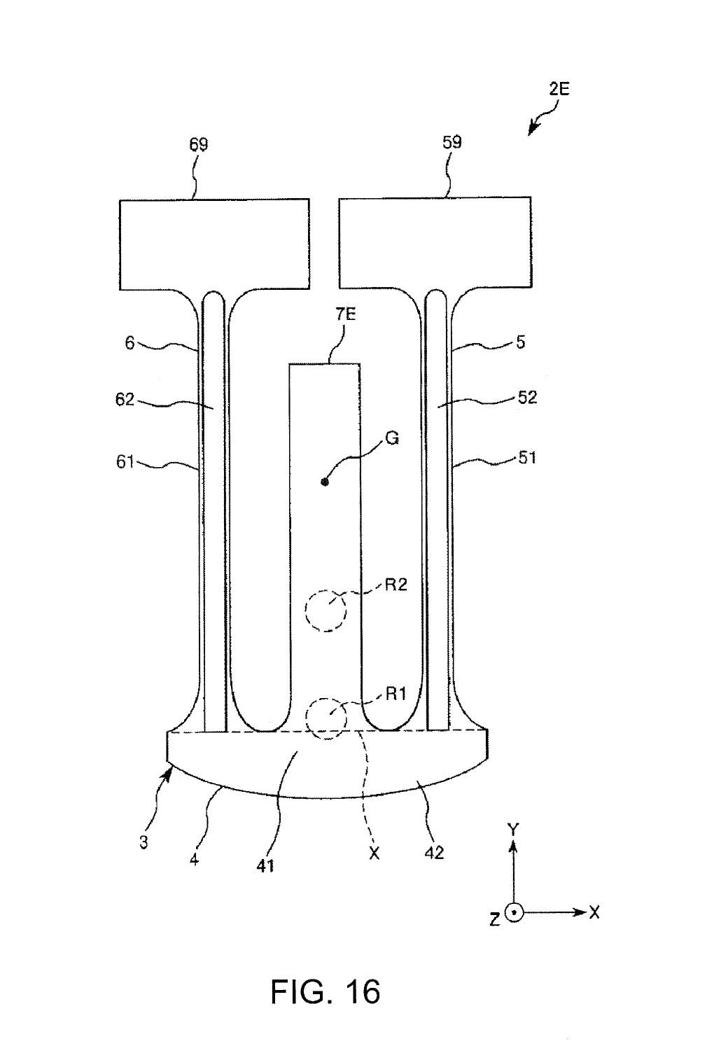

FIG. 16 is a top view of a resonator element included in the resonator according to the sixth embodiment of the invention.

Hereinafter, the resonator according to the sixth embodiment will be described focusing on the differences from the first embodiment described above, and a description of the same matters will be omitted.

The resonator according to the sixth embodiment of the invention is the same as that of the first embodiment described above except that the configuration of a resonator element is different. Meanwhile, the same components as in the first embodiment described above are denoted by the same reference numerals.

As shown in FIG. 16, a supporting arm 7E of a resonator element 2E is provided over a centroid G. That is, the supporting arm 7E is larger in length in the Y-axis direction than the supporting arm 7 of the first embodiment described above. A fixed region R is provided on the base end side of the supporting arm 7E. Meanwhile, a positional relationship between first and second fixation portions R1 and R2 is the same as the positional relationship between the first and second fixation portions R1 and R2 of the first embodiment described above.

In addition, the base end side of the first fixation portion R1 is positioned at a base portion 4 across the base end of the supporting arm 7E when seen in a plan view from the Z-axis direction. That is, the first fixation portion R1 is provided over a boundary between the supporting arm 7E and the base portion 4. Here, in this embodiment, the base end of the supporting arm 7E, that is, a boundary between the supporting arm 7E and the base portion 4 is set to a line segment that connects places where both side surfaces of the supporting arm 7E are connected to the base portion 4, and is shown by a dashed line X in FIG. 16.

Here, similarly to the resonator element 2 of the first embodiment described above, the resonator element 2E is configured so as to vibrate in an X reverse phase mode. However, a combination of the vibration mode and another unnecessary vibration mode leads to an imbalance in vibrating arms 5 and 6, and thus the distal end of the supporting arm 7E involuntarily vibrates in the X-axis direction and the Z-axis direction. For this reason, similarly to the fourth embodiment described above, also in this embodiment, the fixed region R is provided by avoiding the distal end of the supporting arm 7E. Thus, it is possible to further reduce vibration leakage.

Also in the sixth embodiment, the same effects as in the first embodiment described above can be exhibited.

### Seventh Embodiment

Next, a resonator according to a seventh embodiment of the invention will be described.

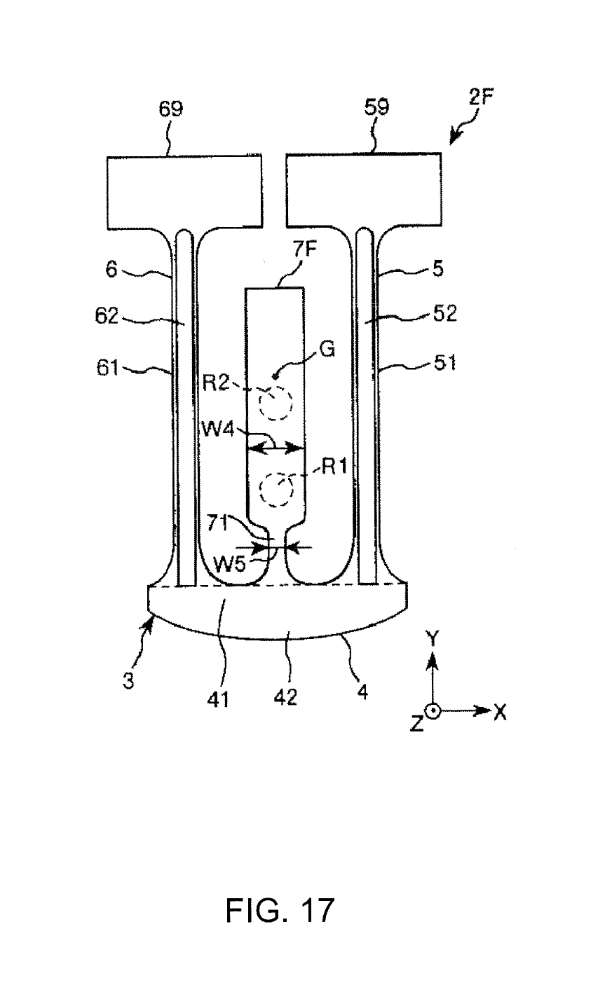

FIG. 17 is a top view of a resonator element included in the resonator according to the seventh embodiment of the invention.

Hereinafter, the resonator according to the seventh embodiment will be described focusing on the differences from the first embodiment described above, and a description of the same matters will be omitted.

The resonator according to the seventh embodiment of the invention is the same as that of the first embodiment described above except that the configuration of a resonator element is different. Meanwhile, the same components as in the first embodiment described above are denoted by the same reference numerals.

As shown in FIG. 17, a supporting arm 7F of a resonator element 2F is provided over a centroid G. In addition, the supporting arm 7F has a narrow width portion 71 having a width (length in the X-axis direction), which is smaller than that of the distal end side, in the base end thereof. A fixed region R is provided on the distal end side with respect to the narrow width portion 71 and is provided on the base end side with respect to the centroid G. Meanwhile, a positional relationship between first and second fixation portions R1 and R2 is the same as the positional relationship between the first and second fixation portions R1 and R2 of the first embodiment described above. The providing of the narrow width portion 71 can keep a resonance frequency in an X common mode (unnecessary vibration mode) away from a resonance frequency in an X reverse phase mode (main mode). For this reason, it is possible to reduce the mixing of an unnecessary vibration with a vibration in the main mode, and the resonator element 2F can exhibit excellent vibration characteristics. Meanwhile, when the resonance frequency in the X reverse phase mode is set to ω0 and the resonance frequency in the X common mode is set to ω1, |ω0−ω1|/ω0 is preferably equal to or greater than 0.12 and is more preferably equal to or greater than 0.20. Thus, it is possible to prominently exhibit the effects described above.

In addition, a width W5 of the narrow width portion 71 is not particularly limited, but it is preferable that the width is equal to or greater than 20% and is equal to or less than 50% of a width W4 of a portion on the distal end side with respect to the narrow width portion. Thus, the above-described effects are further improved, and a vibration of a base portion 4 is not likely to be transmitted by the supporting arm 7F.

Also in the seventh embodiment, the same effects as in the first embodiment described above can be exhibited.

### Eighth Embodiment

Next, a resonator according to an eighth embodiment of the invention will be described.

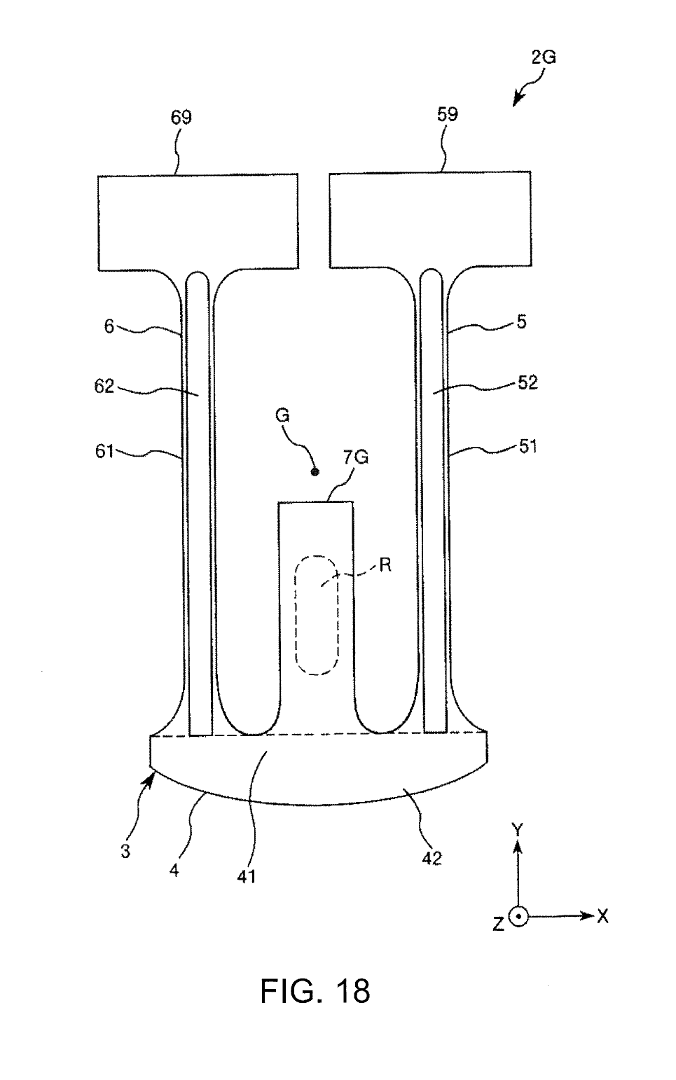

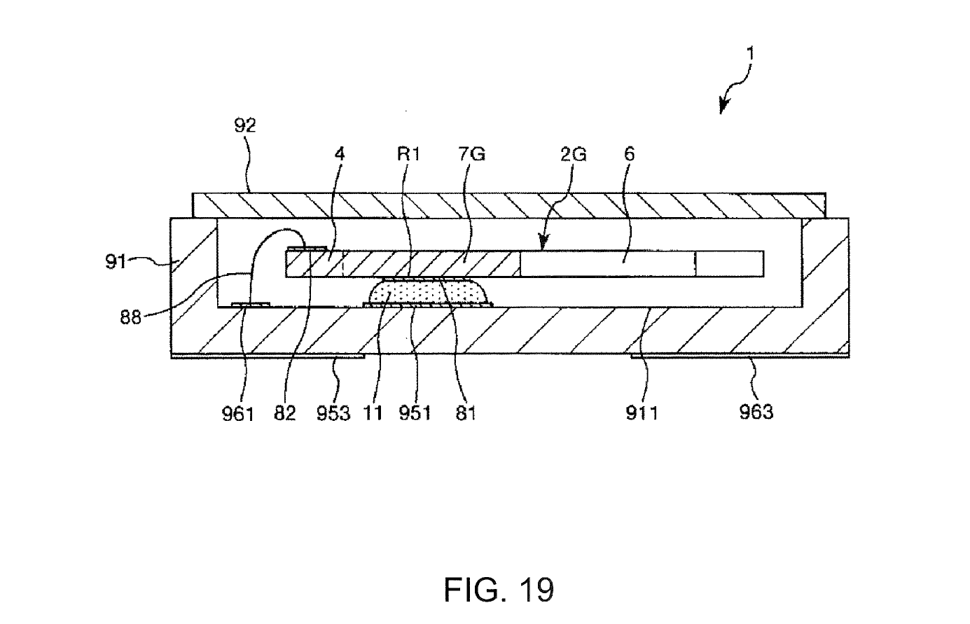

FIG. 18 is a top view of a resonator element included in the resonator according to the eighth embodiment of the invention, and FIG. 19 is a cross-sectional view of the resonator shown in FIG. 18.

Hereinafter, the resonator according to the eighth embodiment will be described focusing on the differences from the first embodiment described above, and a description of the same matters will be omitted.

The resonator according to the eighth embodiment of the invention is the same as that of the first embodiment described above except that the configuration of a resonator element is different. Meanwhile, the same components as in the first embodiment described above are denoted by the same reference numerals.

As shown in FIGS. 18 and 19, a fixed region R of a resonator element 2G is not divided into first and second fixation portions R1 and R2 as in the first embodiment described above. That is, the fixed region R is present as one unified region. A quartz crystal substrate 3 is fixed to a base 91 through a conductive adhesive member 11 by the fixed region R. The fixed region R is provided with a first connection electrode 81, and the first connection electrode 81 is electrically connected to a connecting terminal 951 through the conductive adhesive member 11. In addition, a second connection electrode 82 is provided in the other principal surface (surface on the +Z-axis side) of a base portion 4, and is electrically connected to a connecting terminal 961 through a bonding wire 88. The providing of the above-described fixed region R leads to an increase in a contact area with the conductive adhesive member 11, and thus the fixation to the base 91 can be further stabilized. In addition, since the conductive adhesive member 11 is kept away from the bonding wire (metal wire) 88, it is possible to prevent a short circuit.

Also in the eighth embodiment, the same effects as in the first embodiment described above can be exhibited.

Meanwhile, in the above-described embodiments and modified examples, quartz crystal is used as the material of the resonator element. However, the invention is not limited thereto, and it is possible to use, for example, an oxide substrate such as aluminum nitride (AlN), lithium niobate (LiNbO₃), lithium tantalate (LiTaO₃), lead zirconate titanate (PZT), lithium tetraborate (Li₂B₄O₇), or langasite (La₃Ga₅SiO₁₄), a laminated piezoelectric substrate configured by laminating a piezoelectric material such as aluminum nitride, tantalum pentoxide (Ta₂O₅), and the like on a glass substrate, piezoelectric ceramics, and the like.

In addition, it is possible to form a resonator element using a material other than a piezoelectric material. For example, it is also possible to form a resonator element using a silicon semiconductor material. In addition, a vibration (driving) method of the resonator element is not limited to a piezoelectric driving method. It is also possible to exhibit the configuration of the invention and the effects thereof in resonator elements such as an electrostatic driving type using an electrostatic force and a Lorentz driving type using a magnetic force, in addition to a piezoelectric driving type using a piezoelectric substrate. In addition, the terms used in the specification or the drawings at least once together with a different term having a broader or similar meaning can be replaced with a different term in any portion of the specification or the drawings.

### 2. Oscillator

Next, an oscillator to which the resonator element according to the invention (oscillator according to the invention) is applied will be described.

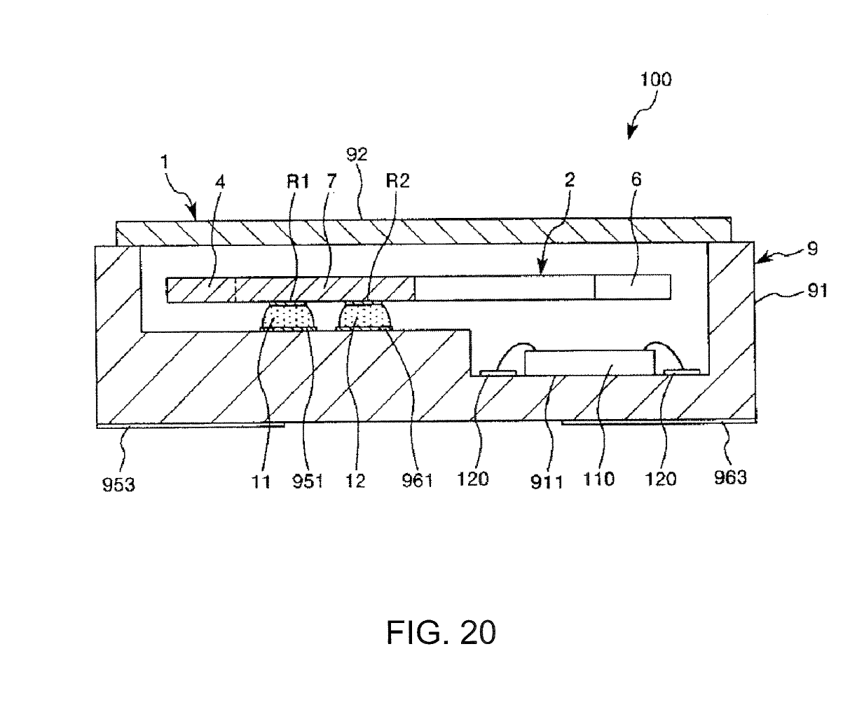

FIG. 20 is a cross-sectional view showing an oscillator according to a preferred embodiment of the invention.

An oscillator 100 shown in FIG. 20 includes a resonator 1 and an IC chip 110 for driving the resonator element 2. Hereinafter, the oscillator 100 will be described focusing on the differences from the resonator described above, and a description of the same matters will be omitted.

As shown in FIG. 20, in the oscillator 100, the IC chip 110 is fixed to the concave portion 911 of the base 91. The IC chip 110 is electrically connected to a plurality of internal terminals 120 formed on the bottom surface of the concave portion 911. The plurality of internal terminals 120 include terminals connected to the connecting terminals 951 and 961 and terminals connected to the external terminals 953 and 963. The IC chip 110 has an oscillation circuit for controlling the driving of the resonator element 2. When the resonator element 2 is driven by the IC chip 110, it is possible to extract a signal having a predetermined frequency.

### 3. Electronic Device

Next, an electronic device to which the resonator element according to the invention is applied (electronic device according to the invention) will be described.

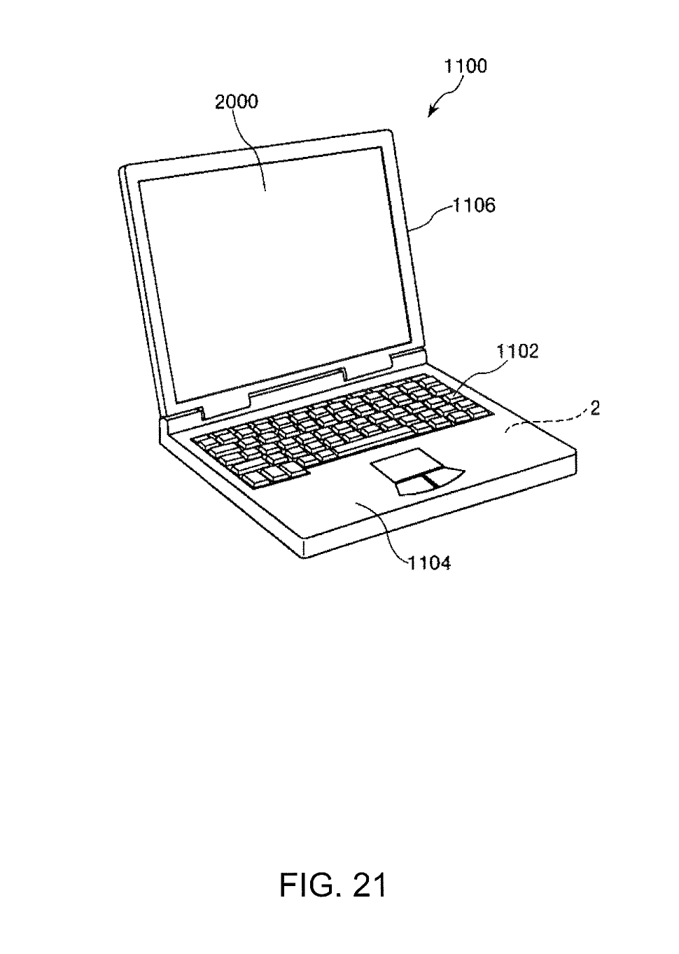

FIG. 21 is a perspective view showing a configuration of a mobile (or notebook) personal computer to which the electronic device including the resonator element according to the invention is applied. In FIG. 21, a personal computer 1100 is configured to include a main body 1104 having a keyboard 1102 and a display unit 1106 having a display portion 2000, and the display unit 1106 is supported so as to be rotatable with respect to the main body 1104 through a hinge structure. The resonator element 2 that functions as a filter, a resonator, a reference clock, and the like is built into the personal computer 1100.

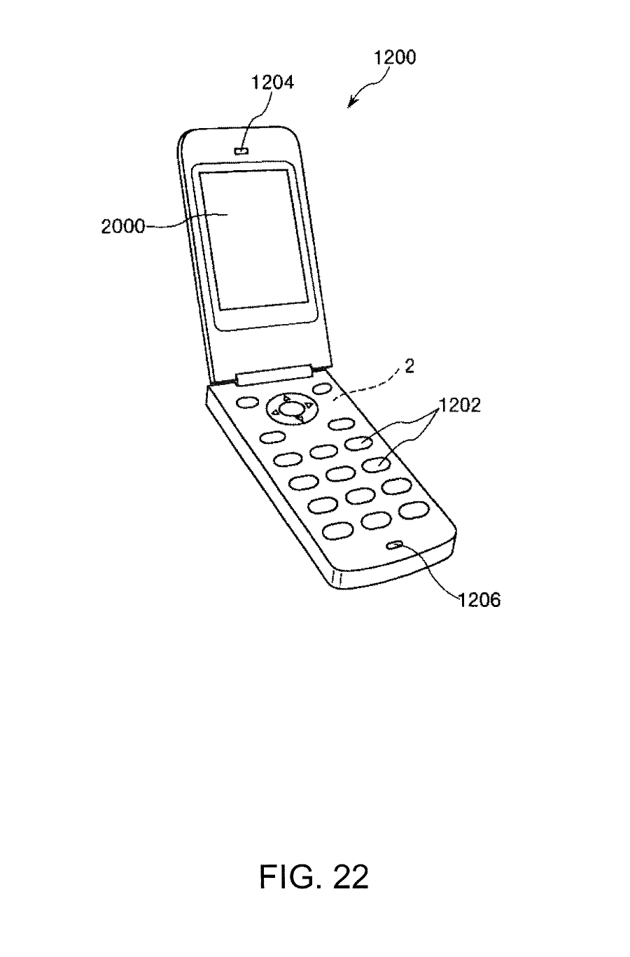

FIG. 22 is a perspective view showing the configuration of a mobile phone (PHS is also included) to which an electronic device including the resonator element according to the invention is applied. In FIG. 22, a mobile phone 1200 includes a plurality of operation buttons 1202, an earpiece 1204, and a mouthpiece 1206, and a display portion 2000 is disposed between the operation buttons 1202 and the earpiece 1204. The resonator element 2 that functions as a filter, a resonator, and the like is built into the mobile phone 1200.

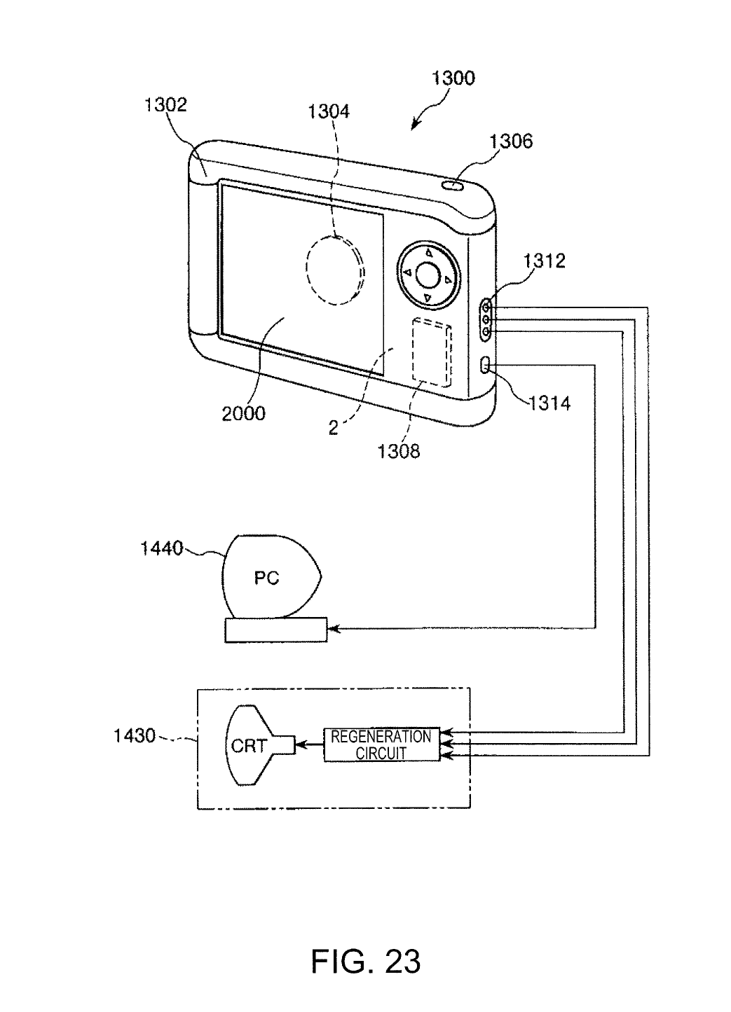

FIG. 23 is a perspective view showing the configuration of a digital still camera to which an electronic device including the resonator element according to the invention is applied. Meanwhile, connection with an external device is simply shown in FIG. 23. Here, a silver halide photography film is exposed to light according to an optical image of a subject in a typical camera, while the digital still camera 1300 generates an imaging signal (image signal) by performing photoelectric conversion of an optical image of a subject using an imaging element, such as a charge coupled device (CCD).

A display portion is provided on the back of a case (body) 1302 in the digital still camera 1300, so that display based on the imaging signal of the CCD is performed. The display portion functions as a viewfinder that displays a subject as an electronic image. In addition, a light receiving unit 1304 including an optical lens (imaging optical system), a CCD, and the like is provided on the front side (back side in FIG. 23) of the case 1302.

When a photographer checks a subject image displayed on the display portion and presses a shutter button 1306, an imaging signal of the CCD at that point in time is transferred and stored in a memory 1308. In addition, in the digital still camera 1300, a video signal output terminal 1312 and an input/output terminal for data communication 1314 are provided on the side surface of the case 1302. In addition, as shown in FIG. 23, a television monitor 1430 is connected to the video signal output terminal 1312 and a personal computer 1440 is connected to the input/output terminal for data communication 1314 when necessary. Further, an imaging signal stored in the memory 1308 may be output to the television monitor 1430 or the personal computer 1440 by a predetermined operation. The resonator element 2 that functions as a filter, a resonator, and the like is built into the digital still camera 1300.

Meanwhile, the electronic device including the resonator element according to the invention can be applied not only to the personal computer (mobile personal computer) shown in FIG. 21, the mobile phone shown in FIG. 22, and the digital still camera shown in FIG. 23 but also to an ink jet type discharge apparatus (for example, an ink jet printer), a laptop type personal computer, a television, a video camera, a video tape recorder, a car navigation apparatus, a pager, an electronic organizer (an electronic organizer with a communication function is also included), an electronic dictionary, an electronic calculator, an electronic game machine, a word processor, a workstation, a video phone, a television monitor for security, electronic binoculars, a POS terminal, medical equipment (for example, an electronic thermometer, a sphygmomanometer, a blood sugar meter, an electrocardiographic measurement device, an ultrasonic diagnostic apparatus, and an electronic endoscope), a fish detector, various measurement apparatuses, instruments (for example, instruments for vehicles, aircraft, and ships), and a flight simulator.

### 4. Moving Object

Next, a moving object to which the resonator element according to the invention (moving object according to the invention) is applied will be described.

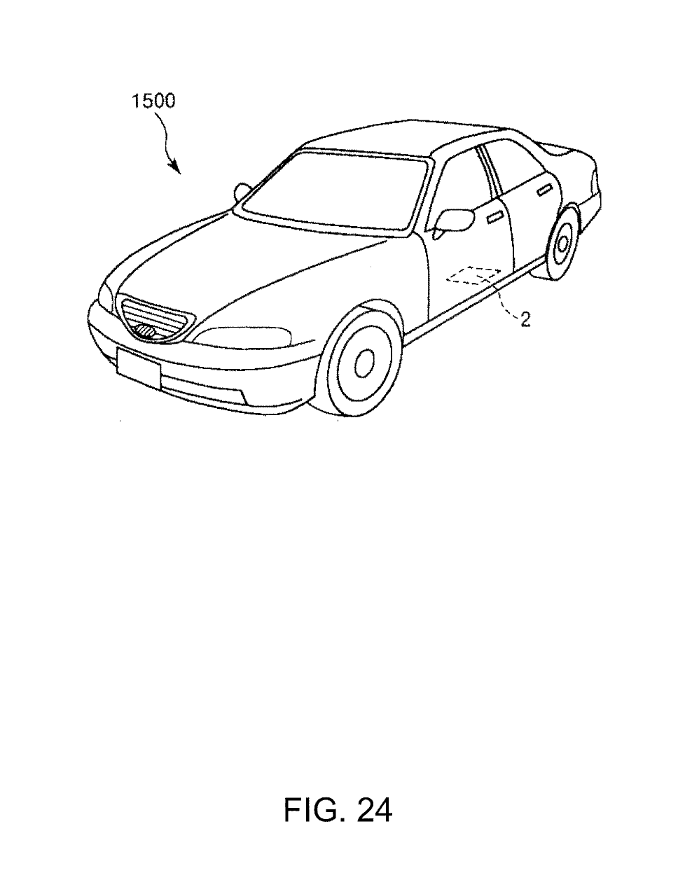

FIG. 24 is a perspective view schematically showing a vehicle as an example of the moving object according to the invention. The resonator element 2 is mounted in a vehicle 1500. The resonator element 2 can be widely applied to an electronic control unit (ECU), such as a keyless entry, an immobilizer, a car navigation system, a car air-conditioner, an anti-lock brake system (ABS), an airbag, a tire pressure monitoring system (TPMS), an engine control, a battery monitor of a hybrid vehicle or an electric vehicle, and a vehicle body position control system.

While the resonator element, the resonator, the oscillator, the electronic device, and the moving object according to the invention have been described with reference to the illustrated embodiments, the invention is not limited thereto, and the configuration of each portion may be replaced with an arbitrary configuration having the same function. In addition, other arbitrary structures may be added to the invention. In addition, the embodiments described above may be appropriately combined.

In the resonator element, a width-decreasing portion having a base portion of which the width (length along an X-axis direction) gradually decreases in a +Y-axis direction may be provided on the distal end side (side opposite to the width-decreasing portion) of the base portion, apart from the above-described width-decreasing portion. By providing the width-decreasing portion, a vibration of a vibrating arm is mainly offset (reduced and absorbed) by the width-decreasing portion, but it is possible to further efficiently reduce and absorb a vibration that cannot be wholly offset by the width-decreasing portion.

What is claimed is:

1. A resonator element comprising:
a base portion;
a pair of vibrating arms that extend in a first direction from the base portion and are arranged along a second direction perpendicular to the first direction; and
a supporting arm that extends in the first direction from the base portion and is disposed between the pair of vibrating arms when seen in a plan view,
the supporting arm being provided with a fixed region that is attached to an object through a fixing member between a centroid of the resonator element and the base portion when seen in the plan view.

2. The resonator element according to claim 1, wherein the fixed region has a length along the first direction which is larger than a width along the second direction.

3. The resonator element according to claim 2, wherein the fixed region has a length along the first direction that is between two and five times the width along the second direction, inclusive.

4. The resonator element according to claim 1, wherein when a distance along the first direction between the centroid and the base portion when seen in a plan view is set to a first distance, the distance along the first direction between a center of the fixed region in the first direction and the base portion is between 0.15 and 0.30 times the first distance, inclusive.

5. The resonator element according to claim 1, wherein when a distance along the first direction between the centroid and the base portion when seen in a plan view is set to a first distance, the distance of the fixed region along the first direction is between the first distance and 0.589 times the first distance, inclusive.

6. The resonator element according to claim 1, wherein the supporting arm overlaps the centroid when seen in the plan view.

7. The resonator element according to claim 1, wherein the fixed region includes, when seen in the plan view,
a first fixing portion; and
a second fixing portion which is spaced apart from the first fixing portion and is positioned on a distal end side of the supporting arm with respect to the first fixing portion.

8. The resonator element according to claim 7, wherein a distance along the first direction between the first fixing portion and the second fixing portion is equal to or greater than 20 μm.

9. A resonator comprising:
the resonator element according to claim 1; and
a package that accommodates the resonator element.

10. A resonator comprising:
the resonator element according to claim 2; and
a package that accommodates the resonator element.

11. An oscillator comprising:
the resonator element according to claim 1; and
an oscillation circuit.

12. An oscillator comprising:
the resonator element according to claim 2; and
an oscillation circuit.

13. An electronic device comprising the resonator element according to claim 1.

14. An electronic device comprising the resonator element according to claim 2.

15. A moving object comprising the resonator element according to claim 1.

16. A moving object comprising the resonator element according to claim 2.

17. A resonator element comprising:
a base portion;
a pair of vibrating arms that extend in a first direction from the base portion; and
a supporting arm extending from the base portion in the first direction between the pair of vibrating arms along a first axis, the first axis being collinear with a centroid of the resonator element and parallel to the pair of vibrating arms;
the supporting arm being provided with a fixed region that is attached to a base object through a fixing member between the supporting arm and the base portion.
